(19) United States
(12) Patent Application Publication
(10) Pub. No.: US 2025/0126787 A1
(43) Pub. Date: Apr. 17, 2025

(54) MEMORY DEVICE AND METHOD OF MANUFACTURING THE MEMORY DEVICE

(71) Applicant: SK hynix Inc., Icheon-si Gyeonggi-do (KR)

(72) Inventors: Do Young KIM, Icheon-si Gyeonggi-do (KR); Eun Mee KWON, Icheon-si Gyeonggi-do (KR)

(73) Assignee: SK hynix Inc., Icheon-si Gyeonggi-do (KR)

(21) Appl. No.: 18/609,652

(22) Filed: Mar. 19, 2024

(30) Foreign Application Priority Data
Oct. 11, 2023 (KR) 10-2023-0135145

(51) Int. Cl. H10B 43/27

(52) U.S. Cl. CPC H10B 43/27

(57) ABSTRACT

The present disclosure includes a memory device and a method of manufacturing the memory device. The memory device includes a channel layer passing through gate lines stacked spaced apart from each other, a channel junction extending on the channel layer, a capping layer surrounded by the channel layer, a void surrounded by the capping layer, a capping pattern surrounded by the channel junction and contacting an upper portion of the capping layer and the void, and a source line positioned on the gate lines and contacting the channel junction.

### CROSS-REFERENCE TO RELATED APPLICATION

The present application claims priority under 35 U.S.C. § 119(a) to Korean patent application number 10-2023-0135145 filed on Oct. 11, 2023, in the Korean Intellectual Property Office, the entire disclosure of which is incorporated by reference herein.

### BACKGROUND

### 1. Technical Field

The present disclosure generally relates to a memory device and a method of manufacturing the memory device, and more particularly, to a memory device manufactured by a wafer bonding technique and a method of manufacturing the memory device that is manufactured by the wafer bonding technique.

### 2. Related Art

A memory device may include a memory cell array in which data is stored, and a peripheral circuit configured to perform a program, read, or erase operation of the memory cell array.

The memory cell array may include a plurality of memory blocks positioned between bit lines and a source line, and each of the plurality of memory blocks may include cell plugs extending in a vertical direction from a substrate. The cell plugs may include source select transistors, memory cells, and drain select transistors. When the memory blocks are positioned on the peripheral circuit, the bit lines may be positioned between the peripheral circuit and the memory blocks, and the source line may be positioned on the memory blocks.

Because the source line is commonly connected to the cell plugs included in each of the memory blocks, as the number of memory blocks increases, a resistance between the source line and the cell plugs may increase, and thus reliability of operations of the memory device using the source line may be reduced.

### SUMMARY

According to an embodiment of the present disclosure, a memory device may include a channel layer passing through gate lines stacked spaced apart from each other, a channel junction extending from the channel layer, a capping layer surrounded by the channel layer, a void surrounded by the capping layer, a capping pattern surrounded by the channel junction and contacting an upper portion of the capping layer and the void, and a source line positioned on the gate lines and contacting the channel junction.

According to an embodiment of the present disclosure, a memory device may include a stack structure including insulating layers and gate lines alternately stacked, a cell plug included in the stack structure and passing through the insulating layers and the gate lines, a channel layer included in the cell plug, a void surrounded by the channel layer, a tunnel insulating layer surrounding the channel layer, a charge trap layer surrounding the tunnel insulating layer, and a blocking layer surrounding the charge trap layer, a channel junction included in the cell plug and extending from the channel layer, a capping pattern included in the cell plug and surrounded by at least a portion of the channel layer and the channel junction, and a source line positioned on the stack structure and contacting the channel junction and the capping pattern.

According to an embodiment of the present disclosure, a method of manufacturing a memory device may include forming a stack structure including a cell plug including a blocking layer passing through first material layers and gate lines alternately stacked, a charge trap layer surrounded by the blocking layer, a tunnel insulating layer surrounded by the charge trap layer, a channel layer surrounded by the tunnel insulating layer, a capping layer surrounded by the channel layer, and a void surrounded by the capping layer, forming a capping pattern filling a portion of an upper portion of the void, performing an ion injection process for converting a portion of the channel layer surrounding the capping pattern into a channel junction having an impurity concentration higher than that of the channel layer, and forming a source line contacting the channel junction on the stack structure.

According to an embodiment of the present disclosure, a method of manufacturing a memory device may include forming a stack structure including a cell plug including a blocking layer extending to a portion of a sacrificial structure positioned at an uppermost end by passing through first material layers and gate lines alternately stacked, a charge trap layer surrounded by the blocking layer, a tunnel insulating layer surrounded by the charge trap layer, a channel layer surrounded by the tunnel insulating layer, a capping layer surrounded by the channel layer, and a void surrounded by the capping layer, exposing a protrusion protruding on the stack structure of the cell plug by removing the sacrificial structure, performing an ion injection process for converting a portion of the channel layer included in the protrusion into a channel junction having an impurity concentration higher than that of the channel layer, exposing the void by removing a portion of the blocking layer, the charge trap layer, the tunnel insulating layer, and the channel junction included in the protrusion, forming a capping pattern filling a portion of an upper portion of the void, and forming a source line contacting the channel junction on the stack structure.

### BRIEF DESCRIPTION OF THE DRAWINGS

FIG. 1 is a diagram illustrating a memory device.

FIG. 2 is a diagram illustrating a memory cell array.

FIG. 3 is a diagram illustrating a memory block.

FIG. 4 is a diagram illustrating a memory device according to a first embodiment of the present disclosure.

FIGS. 5A, 5B, 5C, 5D, 5E, 5F, 5G, 5H, 5I, 53, 5K, 5L, and 5M are diagrams illustrating a method of manufacturing a memory device according to the first embodiment of the present disclosure.

FIG. 6 is a diagram illustrating a memory device according to a second embodiment of the present disclosure.

FIGS. 7A, 7B, 7C, 7D, 7E, 7F, and 7G are diagrams illustrating a method of manufacturing a memory device according to the second embodiment of the present disclosure.

FIG. 8 is a diagram illustrating a memory device according to a third embodiment of the present disclosure.

FIGS. 9A, 9B, 9C, 9D, 9E, 9F, 9G, and 9H are diagrams illustrating a method of manufacturing a memory device according to the third embodiment of the present disclosure.

FIG. 10 is a diagram illustrating a memory device according to a fourth embodiment of the present disclosure.

FIGS. 11A, 11B, 11C, 11D, 11E, 11F, and 11G are diagrams illustrating a method of manufacturing a memory device according to the fourth embodiment of the present disclosure.

FIG. 12 is a diagram illustrating a memory device according to a fifth embodiment of the present disclosure.

FIGS. 13A, 13B, 13C, 13D, and 13E are diagrams illustrating a method of manufacturing a memory device according to the fifth embodiment of the present disclosure.

FIG. 14 is a diagram illustrating a memory card system to which a memory device of the present disclosure is applied.

FIG. 15 is a diagram illustrating a solid state drive (SSD) system to which a memory device of the present disclosure is applied.

### DETAILED DESCRIPTION

Specific structural or functional descriptions disclosed below are exemplified to describe an embodiment according to the concept of the present disclosure. The embodiment according to the concept of the present disclosure is not construed as being limited to the embodiments described below, and may be variously modified and replaced with other equivalent embodiments.

Hereinafter, terms such as first and second may be used to describe various components, but the components are not limited by the terms. The terms are used for the purpose of distinguishing one component from another component. These terms are only used to distinguish one element from another element and are not intended to imply an order or number of elements. Thus, a first element in some embodiments could be termed a second element in other embodiments without departing from the teachings of the present disclosure. It will be understood that when an element or layer etc., is referred to as being “on,” “connected to” or “coupled to” another element or layer etc., it can be directly on, connected or coupled to the other element or layer etc., or intervening elements or layers etc., may be present. In contrast, when an element or layer etc., is referred to as being “directly on,” “directly connected to” or “directly coupled to” another element or layer etc., there are no intervening elements or layers etc., present.

An embodiment of the present disclosure provides a memory device and a method of manufacturing the memory device capable of reducing a resistance between a source line and cell plugs.

An embodiment of the present technology may uniformly form an impurity concentration of a channel junction, thereby improving reliability of the memory device.

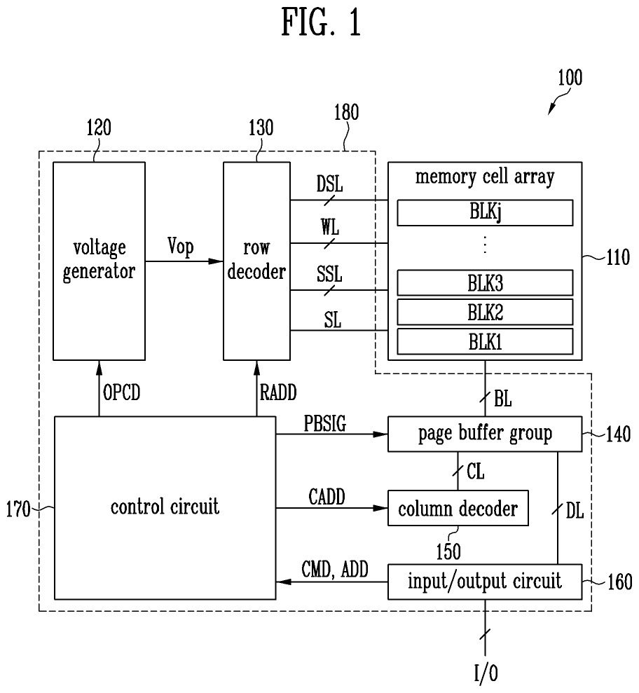

FIG. 1 is a diagram illustrating a memory device.

Referring to FIG. 1, the memory device 100 may include a memory cell array 110 and a peripheral circuit 180.

The memory cell array 110 may include first to j-th memory blocks BLK1 to BLKj. Each of the first to j-th memory blocks BLK1 to BLKj may include memory cells capable of storing data. Drain select lines DSL, word lines WL, source select lines SSL, and a source line SL may be connected to each of the first to j-th memory blocks BLK1 to BLKj, and a bit line BL may be commonly connected to the first to j-th memory blocks BLK1 to BLKj.

The first to j-th memory blocks BLK1 to BLKj may be formed in a three-dimensional structure. The memory blocks having the three-dimensional structure may include memory cells stacked on a substrate in a vertical direction.

The memory cells may store 1 bit or 2 bits or more of data according to a program method. For example, a method in which 1 bit of data is stored in one memory cell is referred to as a single level cell method, and a method in which 2 bits of data is stored in one memory cell is referred to as a multi-level cell method. A method in which 3 bits of data is stored in one memory cell is referred to as a triple level cell method, and a method in which 4 bits of data is stored in one memory cell is referred to as a quad level cell method. In addition to this, five bits or more of data may be stored in one memory cell.

The peripheral circuit 180 may be configured to perform the program operation of storing data in the memory cell array 110, the read operation of outputting the data stored in the memory cell array 110, and the erase operation of erasing the data stored in the memory cell array 110. For example, the peripheral circuit 180 may include a voltage generator 120, a row decoder 130, a page buffer group 140, a column decoder 150, an input/output circuit 160, and a control circuit 170.

The voltage generator 120 may generate various operation voltages Vop used for the program operation, the read operation, or the erase operation in response to an operation code OPCD. For example, the voltage generator 120 may be configured to generate program voltages, turn-on voltages, turn-off voltages, negative voltages, precharge voltages, verify voltages, read voltages, pass voltages, or erase voltages in response to the operation code OPCD. The operation voltages Vop generated by the voltage generator 120 may be applied to the drain select lines DSL, the word lines WL, the source select lines SSL, and the source line SL of memory block selected through the row decoder 130.

The program voltages may be voltages applied to a selected word line among the word lines WL during the program operation, and may be used to increase a threshold voltage of memory cells connected to the selected word line. The turn-on voltages may be applied to the drain select lines DSL or the source select lines SSL, and may be used to turn on drain select transistors or source select transistors. The turn-off voltages may be applied to the drain select lines DSL or the source select lines SSL, and may be used to turn off the drain select transistors or the source select transistors. For example, the turn-off voltage may be set to 0V. The precharge voltages may be a voltage higher than 0V, and may be applied to bit lines during the read operation. The verify voltages may be used during a verify operation for determining whether a threshold voltage of selected memory cells is increased to a target level. The verify voltages may be set to various levels according to the target level, and may be applied to the selected word line.

The read voltages may be applied to the selected word line during the read operation of the selected memory cells. For example, the read voltages may be set to various levels according to a program method of the selected memory cells. The pass voltages may be voltages applied to unselected word lines among the word lines WL during the program or read operation, and may be used to turn on memory cells connected to the unselected word lines.

The erase voltages may be used during the erase operation for erasing memory cells included in the selected memory block, and may be applied to the source line SL.

The row decoder 130 may be configured to transmit the operation voltages Vop to the drain select lines DSL, the word lines WL, the source select lines SSL, and the source line SL connected to the selected memory block according to a row address RADD. For example, the row decoder 130 may be connected to the voltage generator 120 through global lines, and may be connected to the first to j-th memory blocks BLK1 to BLKj through the drain select lines DSL, the word lines WL, the source select lines SSL, and the source line SL.

The page buffer group 140 may include page buffers PB1 to PBn (not shown) connected to the first to j-th memory blocks BLK1 to BLKj. Each of the page buffers (not shown) may be connected to the first to j-th memory blocks BLK1 to BLKj through bit lines BL. During the read operation, the page buffers (not shown) may sense a current or a voltage of the bit lines which varies according to threshold voltages of the selected memory cells, and store the sensed data, in response to page buffer control signals PBSIG.

The column decoder 150 may be configured so that data is transmitted between the page buffer group 140 and the input/output circuit 160 in response to a column address CADD. For example, the column decoder 150 may be connected to the page buffer group 140 through column lines CL and may transmit enable signals through the column lines CL. The page buffers (not shown) included in the page buffer group 140 may receive or output the data through data lines DL in response to the enable signals.

The input/output circuit 160 may be configured to receive or output a command CMD, an address ADD, or data through input/output lines I/O. For example, the input/output circuit 160 may transmit the command CMD and the address ADD received from an external controller to the control circuit 170 through the input/output lines I/O, and transmit the data received from the external controller to the page buffer group 140 through the input/output lines I/O. Alternatively, the input/output circuit 160 may output the data received from the page buffer group 140 to the external controller through the input/output lines I/O.

The control circuit 170 may output the operation code OPCD, the row address RADD, the page buffer control signals PBSIG, and the column address CADD in response to the command CMD and the address ADD. For example, when the command CMD input to the control circuit 170 is a command corresponding to the program operation, the control circuit 170 may control devices included in the peripheral circuit 180 to perform the program operation of a memory block selected by the address ADD. When the command CMD input to the control circuit 170 is a command corresponding to the read operation, the control circuit 170 may control the devices included in the peripheral circuit 180 to perform the read operation of the memory block selected by the address and output the read data. When the command CMD input to the control circuit 170 is a command corresponding to the erase operation, the control circuit 170 may control the devices included in the peripheral circuit 180 to perform the erase operation of the selected memory block.

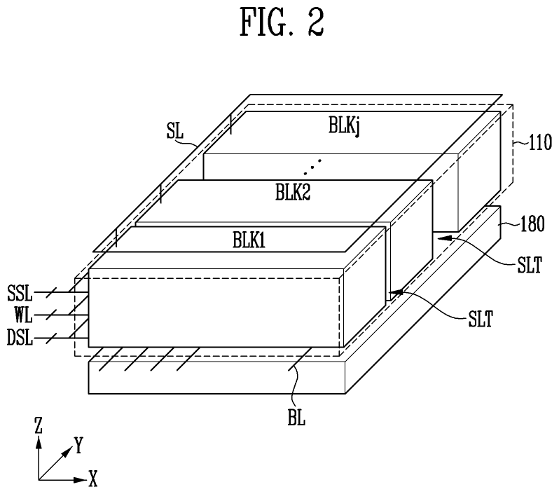

FIG. 2 is a diagram illustrating the memory cell array.

Referring to FIG. 2, the memory cell array 110 may be positioned on the peripheral circuit 180. The memory cell array 110 may include first to j-th memory blocks BLK1 to BLKj. Each of the first to j-th memory blocks BLK1 to BLKj may include cell plugs extending in a Z direction. Each of the cell plugs may include source select transistors, memory cells, and drain select transistors. The first to j-th memory blocks BLK1 to BLKj may be arranged to be spaced apart from each other along a Y direction and may extend along an X direction.

The first to j-th memory blocks BLK1 to BLKj may be positioned between the source line SL and the bit lines BL. The source line SL may be positioned on the first to j-th memory blocks BLK1 to BLKj, and the bit lines BL may be positioned under the first to j-th memory blocks BLK1 to BLKj. Therefore, the bit lines BL may be positioned between the memory cell array 110 and the peripheral circuit 180. The source line SL may be connected to the cell plugs on the first to j-th memory blocks BLK1 to BLKj, and the bit lines BL may be connected to the cell plugs under the first to j-th memory blocks BLK1 to BLKj.

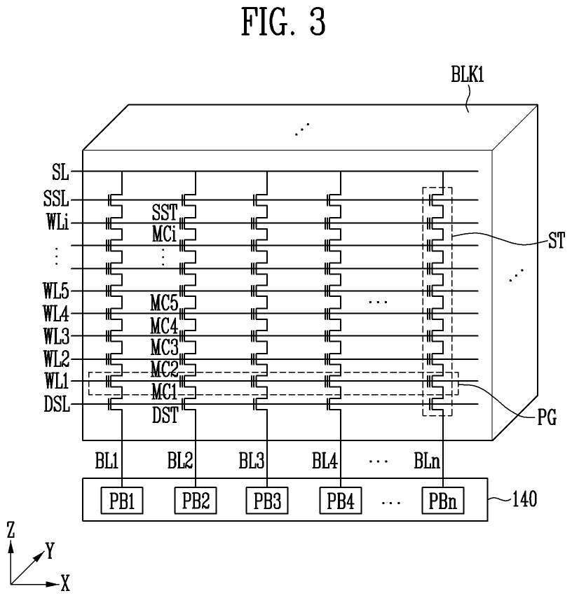

FIG. 3 is a diagram illustrating a memory block.

Referring to FIG. 3, the first memory block BLK1 among the first to j-th memory blocks BLK1 to BLKj shown in FIG. 2 is shown as an example.

The first memory block BLK1 may include a plurality of cell strings ST connected between the source line SL and first to n-th bit lines BL1 to BLn. The cell strings ST may be commonly connected to the source line SL. Among the cell strings ST, the cell strings ST arranged along the X direction may be respectively connected to the first to n-th bit lines BL1 to BLn, and the cell strings ST arranged along the Y direction may be connected to the same bit line among the first to n-th bit lines BL1 to BLn.

The first to n-th bit lines BL1 to BLn may be electrically connected to first to n-th page buffers PB1 to PBn included in the page buffer group 140, respectively. For example, the first bit line BL1 may be electrically connected to the first page buffer PB1, and the n-th bit line BLn may be electrically connected to the n-th page buffer PBn.

Each of the cell strings ST may include a source select transistor SST, first to i-th memory cells MC1 to MCi, and a drain select transistor DST. The cell string ST connected to the first bit line BL1 among the plurality of cell strings ST is described as an example as follows.

The drain select transistor DST may be connected between the first bit line BL1 and the first memory cell MC1, and the source select transistor SST may be connected between the i-th memory cell MCi and the source line SL. The first to i-th memory cells MC1 to MCi may be connected between the drain select transistor DST and the source select transistor SST. The number of drain select transistors DST and source select transistors SST is not limited to the number shown in FIG. 3. In addition to the first to i-th memory cells MC1 to MCi, dummy cells may be further connected between the drain select transistor DST and the source select transistor SST. The first to i-th memory cells MC1 to MCi may store user data or normal data, and the dummy cells may store dummy data.

Gates of the drain select transistors DST included in different cell strings ST may be connected to a drain select line DSL. Gates of the first to i-th memory cells MC1 to MCi included in different cell strings ST may be connected to first to i-th word lines WL1 to WLi. Gates of the source select transistors SST included in different cell strings ST may be connected to a source select line SSL. A group of memory cells included in the cell strings ST arranged in the X direction and connected to the same word line may become a page PG. In the memory device, a program operation or a read operation of a selected memory block may be performed in a page PG unit.

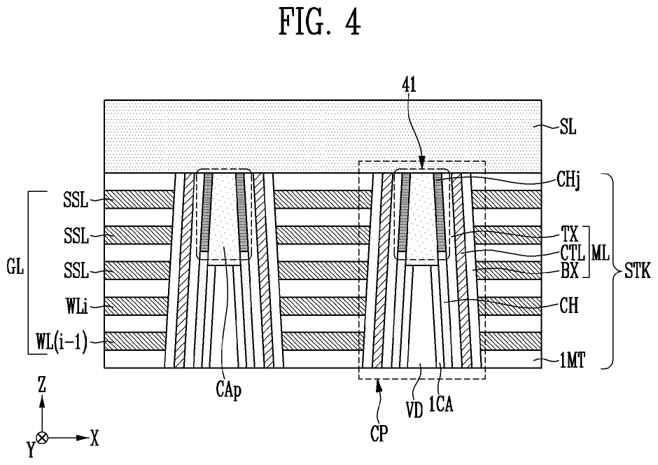

FIG. 4 is a diagram illustrating a memory device according to a first embodiment of the present disclosure.

Referring to FIG. 4, the source line SL may be positioned on a stack structure STK. For example, the source line SL may be positioned on the gate lines GL and may contact the channel junction 41. The stack structure STK may include elements configuring the memory block. A cross section shown in FIG. 4 is a view of a portion of the drawing shown in FIG. 3 cut along an XZ plane.

The stack structure STK may include first material layers 1MT and gate lines GL alternately stacked, and may including cell plugs CP passing through the first material layers 1MT and the gate lines GL. The first material layers 1MT may be formed of an insulating material and be referred to as insulating layers for insulating between the gate lines GL. For example, the first material layers 1MT may be an oxide layer. The gate lines GL may be formed of a conductive material. For example, the gate lines GL may be formed of a metal material such as tungsten (W), molybdenum (Mo), cobalt (Co), and nickel (Ni), or a semiconductor material such as silicon (Si) or polysilicon (Poly-Si), but are not limited thereto. The gate lines GL may be used as the word lines WL(i−1) and WLi or the source select lines SSL, and in addition, the gate lines GL may be used as the drain select lines DSL shown in FIG. 3.

The cell plugs CP may contact the source line SL by passing through the first material layers 1MT and the gate lines GL. Each of the cell plugs CP may include a memory layer ML, a channel layer CH, a channel junction CHj, a first capping layer 1CA, a capping pattern CAp, and a void VD. The memory layer ML may surround a side surface of the channel layer CH and the channel junction CHj.

The channel layer CH may be formed in a cylindrical shape. The channel layer CH may be formed of polysilicon. The channel junction CHj may be a region where an impurity is injected into the channel layer CH, and may be formed in a portion of an upper region 41 of the channel layer CH. For example, the channel junction CHj may be formed by injecting an N-type impurity into the channel layer CH, or may be formed by injecting a mixture of N-type and P-type impurities. For example, the N-type impurity may include phosphorus or arsenic, and the P-type impurity may include boron or BF2. The channel junction CHj may be positioned between the source line SL and the channel layer CH. For example, the channel junction CHj may extend from the channel layer CH as shown in FIG. 4. Because the channel junction CHj is a junction formed by injecting an impurity into the channel layer CH, the channel junction CHj may have an impurity concentration higher than that of the channel layer CH. Therefore, the channel junction CHj may have a resistance lower than that of the channel layer CH. In an embodiment, a resistance between the source line SL and the channel layer CH may be reduced by the channel junction CHj.

The first capping layer 1CA may be formed along an inner side surface of the channel layer CH. The first capping layer 1CA may be an insulating material. For example, the first capping layer 1CA may be an oxide layer. In an embodiment, the first capping layer 1CA does not completely fill an inner region surrounded by the channel layer CH. Therefore, the void VD may be formed in a region surrounded by the first capping layer 1CA.

The capping pattern CAp may be surrounded by the channel junction CHj and a portion of the channel layer CH positioned under the channel junction CHj, and may be positioned between the first capping layer 1CA and the source line SL. In an embodiment, the capping pattern CAp may contact with an upper portion of the first capping layer 1CA and the void VD as shown in FIG. 4. According to a size or a position of the void VD, the capping pattern CAp and the void VD may or might not contact each other. For example, when the capping pattern CAp and the void VD do not contact each other, the first capping layer 1CA may be positioned between the capping pattern CAp and the void VD (not shown). Hereinafter, embodiments having a structure in which the capping pattern CAp and the void VD contact each other are described. In an embodiment, the capping pattern CAp may prevent or mitigate a phenomenon that the source line SL flows into the void VD in a manufacturing process of the memory device, and may prevent or mitigate a phenomenon that an impurity is excessively injected into the channel layer CH in an impurity injection process for forming the channel junction CHj. Therefore, in an embodiment, the channel junction CHj into which the impurity is uniformly injected may be formed. A lower surface of the capping pattern CAp may be positioned lower or higher than a lower surface of the channel junction CHj. Alternatively, the lower surface of the capping pattern CAp may be positioned on the same plane as the lower surface of the channel junction CHj. The capping pattern CAp may be formed of an insulating material. For example, the capping pattern CAp may be formed of an oxide layer. An upper surface of the capping pattern CAp may contact the source line SL. A depth of the capping pattern CAp is not limited to a specific depth. For example, the lower surface of the capping pattern CAp may be positioned in a region where the source select lines SSL are positioned. The void VD may be an air gap surrounded by the first capping layer 1CA. Because, in an embodiment, a region surrounded by the first capping layer 1CA is the void VD, interference of the Z direction may be reduced during an operation of the memory device. In an embodiment, an upper surface of the tunnel insulating layer TX, the charge trap layer CTL, the blocking layer BX, the channel junction CHj, and the capping pattern CAp is substantially flat with an upper surface of the stack structure STK as shown in FIG. 4. In some embodiment, the upper direction may be the Z direction.

The memory layer ML may include a tunnel insulating layer (tunnel isolation layer) TX surrounding the channel layer CH and the channel junction CHj, a charge trap layer CTL surrounding the tunnel insulating layer TX, and a blocking layer BX surrounding the charge trap layer CTL. The tunnel insulating layer TX may be formed of an oxide layer, for example, a silicon oxide layer. The charge trap layer CTL may be a layer for trapping a negative charge during the program operation and may be formed of a nitride layer. The blocking layer BX may be formed of an oxide layer, for example, a silicon oxide layer.

The source line SL may be positioned on the stack structure STK, and may contact an upper surface of the first material layer 1MT, the capping pattern CAp, the channel junction CHj, the tunnel insulating layer TX, the charge trap layer CTL, and the blocking layer BX. The source line SL may be formed of a conductive material, for example, polysilicon.

A method of manufacturing the memory device according to the first embodiment of the present disclosure is described as follows.

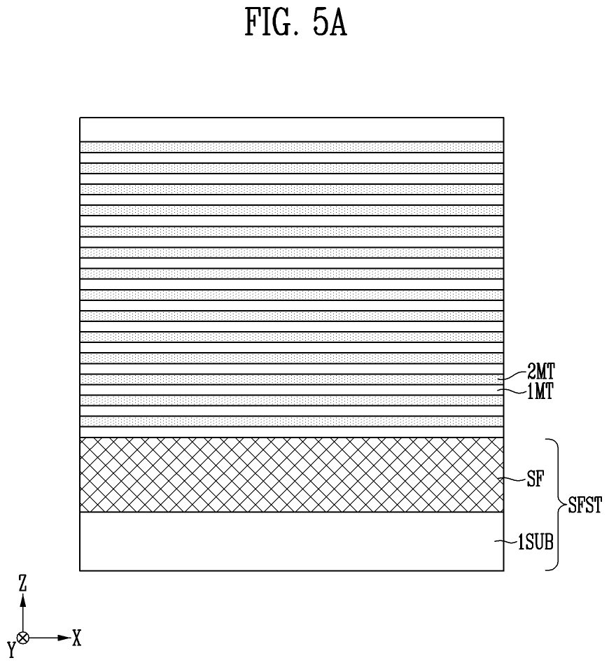

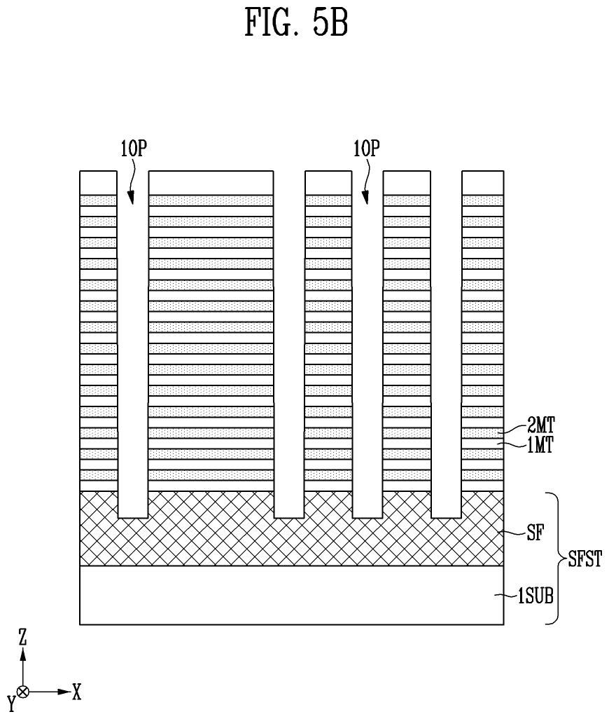

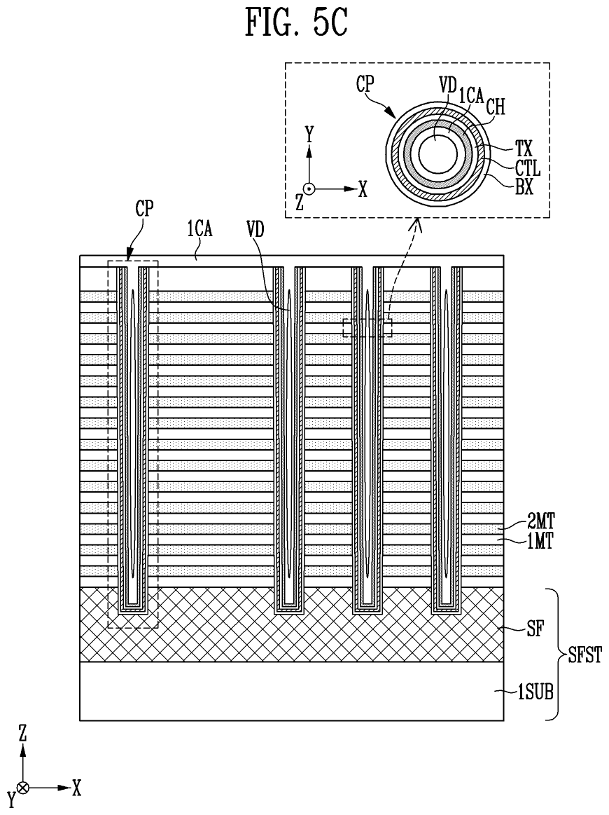

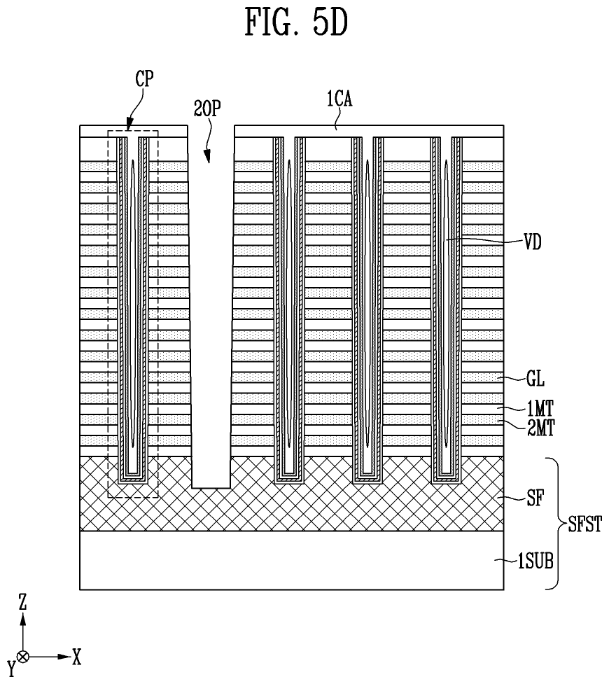

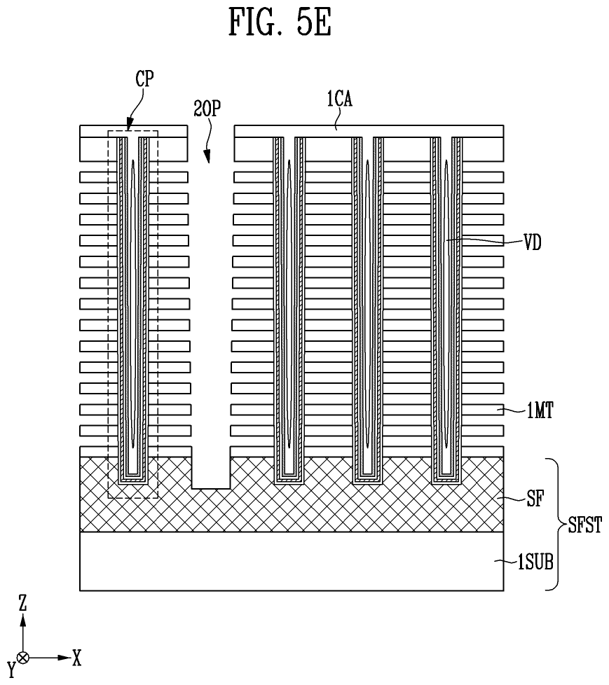

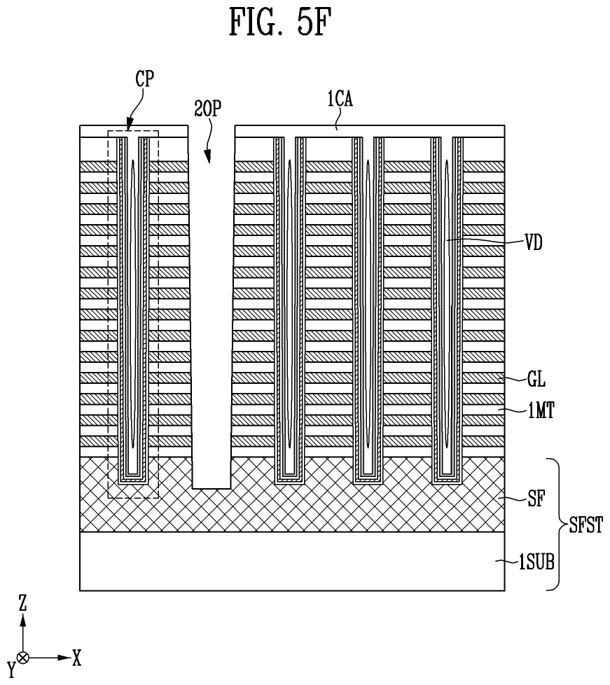

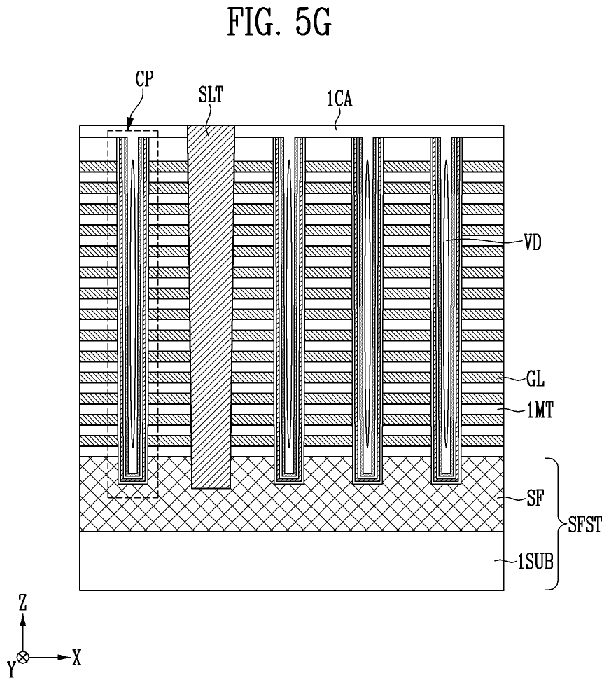

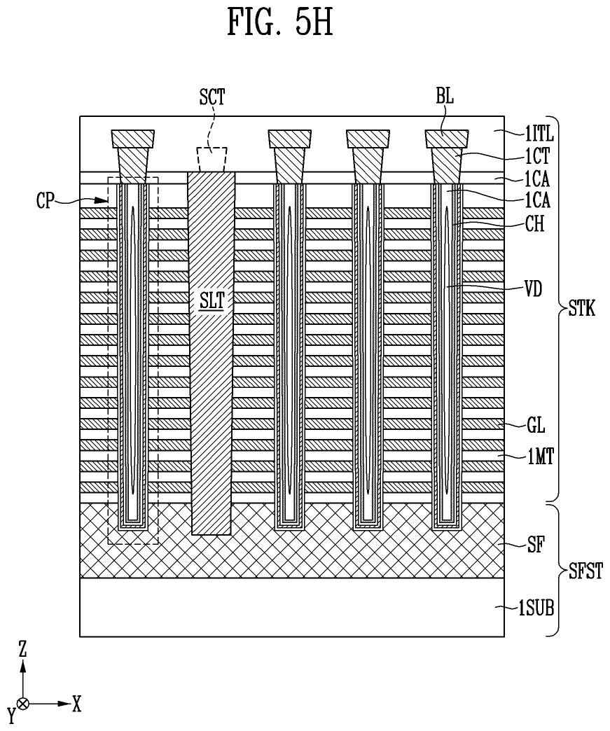

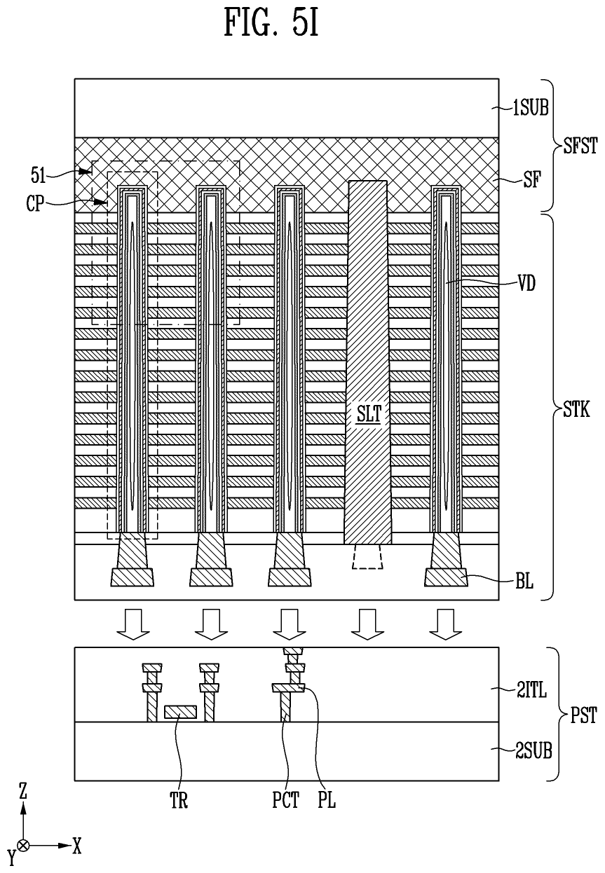

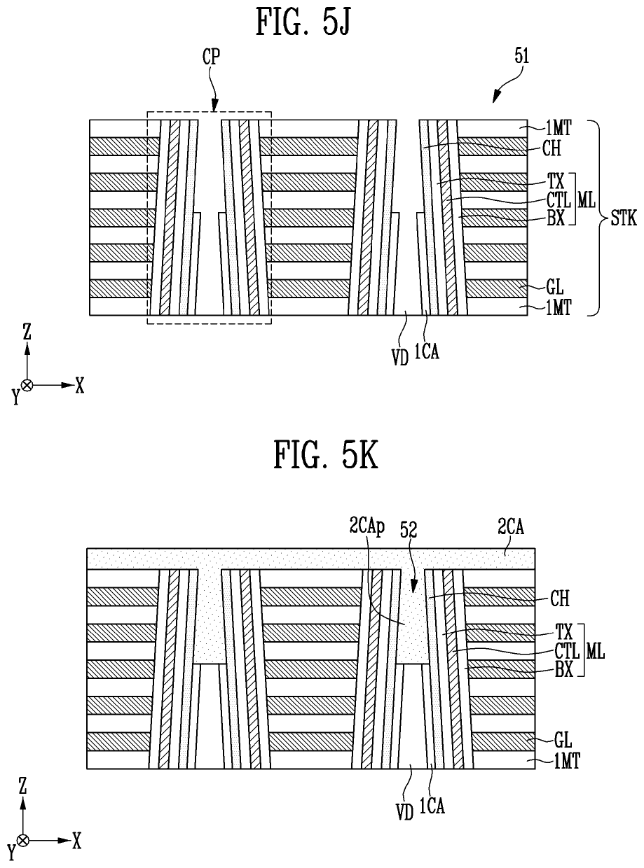

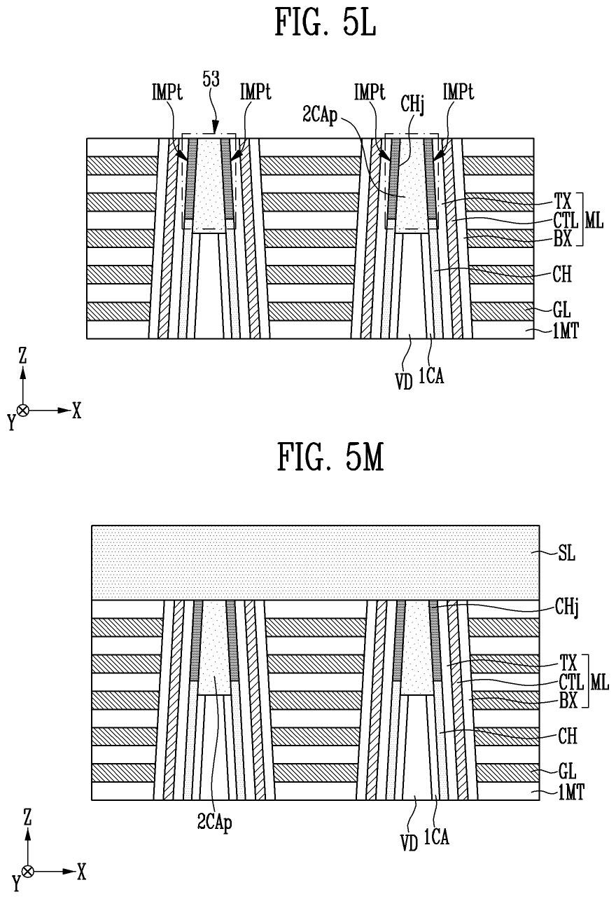

FIGS. 5A to 5M are diagrams illustrating the method of manufacturing the memory device according to the first embodiment of the present disclosure.

Referring to FIG. 5A, the first and second material layers 1MT and 2MT may be alternately stacked on a sacrificial structure SFST. The sacrificial structure SFST may include a first substrate 1SUB and a sacrificial layer SF. The first substrate 1SUB may be a silicon substrate. The sacrificial layer SF may be silicon or polysilicon.

The first material layers 1MT may be an insulating material, and the second material layers 2MT may be a sacrificial material. The sacrificial material is a material that is removed in a subsequent process. For example, the first material layers 1MT may be an oxide layer, and the second material layers 2MT may be a nitride layer. The first material layers 1MT may be positioned at the lowermost portion and the uppermost portion of the first and second material layers 1MT and 2MT alternately stacked.

Referring to FIG. 5B, first openings 10P may be formed in a portion of the first and second material layers 1MT and 2MT and the sacrificial structure SFST. For example, an etching process for forming the first openings 10P extending to a portion of the sacrificial structure SFST by passing through the first and second material layers 1MT and 2MT may be performed. The etching process may be performed as an anisotropic dry etching process. The etching process may be performed until the sacrificial layer SF is exposed. Therefore, a portion of the first and second material layers 1MT and 2MT and a portion of the sacrificial layer SF may be exposed through a side surface of the first openings 10P, and a portion of the sacrificial layer SF may be exposed through a lower surface of the first openings 10P.

Referring to FIG. 5C, the cell plugs CP may be formed in the first openings 10P of FIG. 5B. For example, the blocking layer BX, the charge trap layer CTL, the tunnel insulating layer TX, the channel layer CH, and the first capping layer 1CA may be sequentially formed along the side surface and the lower surface of the first openings 10P. The blocking layer BX may be formed of an oxide layer. The charge trap layer CTL may be formed of a nitride layer. The tunnel insulating layer TX may be formed of an oxide layer. The channel layer CH may be formed of a polysilicon layer. After the channel layer CH is formed, the first capping layer 1CA may be formed on the entire structure in a state in which a region surrounded by the channel layer CH is empty. In order to form the void VD in the cell plugs CP, the first capping layer 1CA may be formed of a material of which a step coverage is low. For example, the first capping layer 1CAP may be formed of an insulating material. For example, the first capping layer 1CA may be formed as an oxide layer. The first capping layer 1CA may be formed along a surface of a region surrounded by the channel layer CH. When the first capping layer 1CA is formed, before the region surrounded by the channel layer CH is completely filled with the first capping layer 1CA, an upper portion of an opening surrounded by the channel layer CH may be covered by the first capping layer 1CA. Accordingly, the void VD, which is an empty space in the cell plugs CP, may be formed. For example, the first capping layer 1CA may be formed in a side, an upper portion, and a lower portion of the void VD.

Referring to FIG. 5D, an etching process for forming a second opening 20P in a partial region between the cell plugs CP may be performed. For example, the second opening 20P may be a trench or a hole for forming the slit SLT of FIG. 2. The etching process for forming the second opening 20P may be performed in an anisotropic dry etching process method. The second opening 20P may expose a portion of the sacrificial structure SFST by passing through the first capping layer 1CA and the first and second material layers 1MT and 2MT. For example, the first capping layer 1CA, a portion of the first and second material layers 1MT and 2MT, and a portion of the sacrificial layer SF may be exposed through a side surface of the second opening 20P, and a portion of the sacrificial layer SF may be exposed through a lower surface.

Referring to FIG. 5E, an etching process for removing the second material layers 2MT of FIG. 5D exposed through the second opening 20P may be performed. For example, the etching process may be performed in a wet etching method.

Referring to FIG. 5F, the gate lines GL may be formed between the first material layers 1MT. The gate lines GL may be formed of a conductive material. The conductive material for the gate lines GL may be formed through the second opening 20P. The conductive material for the gate lines GL may be a metal material such as tungsten (W), molybdenum (Mo), cobalt (Co), and nickel (Ni), or a semiconductor such as silicon (Si) or polysilicon (Poly-Si), but is not limited thereto. When the conductive material for the gate lines GL is formed, because the conductive material may extend in a vertical direction along the side surface of the second opening 20P, an etching process for electrically blocking the gate lines GL formed in different layers may be further performed. The first material layers 1MT and the gate lines GL alternately stacked may be exposed through the side surface of the second opening 20P, by the etching process.

Referring to FIG. 5G, the slit SLT may be formed in the second opening 20P of FIG. 5F. The slit SLT may be formed of an insulating material or a conductive material. When the slit SLT is formed of the conductive material, an insulating material that electrically blocks the conductive material and the gate lines GL from each other may be further formed.

Referring to FIG. 5H, a first interlayer insulating layer 1ITL, first contact plugs 1CT, and the bit lines BL may be formed on the entire structure including the slit SLT. For example, the first contact plugs 1CT may respectively contact an upper portion of the cell plugs CP. The bit lines BL may respectively contact an upper portion of the first contact plugs 1CT. The bit lines BL may be formed of a conductive material. The first contact plugs 1CT may be formed of a conductive material to electrically connect the bit lines BL and the channel layer CH of the cell plugs CP. The first interlayer insulating layer 1ITL may be an insulating material filled between the first contact plugs 1CT and the bit lines BL. Accordingly, the stack structure STK may be formed on the sacrificial structure SFST. When the slit SLT is formed of a conductive material, a slit contact plug SCT for transferring a voltage to the slit SLT may be further formed on the slit SLT.

Referring to FIG. 5I, a peripheral structure PST including the peripheral circuit 180 of FIG. 1 may be formed. The peripheral circuit may be formed on a second substrate 2SUB. For example, the peripheral circuit may include transistors TR, peripheral contact plugs PCT, and peripheral lines PL. The transistors TR, the peripheral contact plugs PCT, and the peripheral lines PL may have various patterns according to the peripheral circuit. A second interlayer insulating layer 2ITL may be formed between the transistors TR, the peripheral contact plugs PCT, and the peripheral lines PL.

Subsequently, the sacrificial structure SFST and the stack structure STK described with reference to FIG. 5H are flipped over, and the flipped stack structure STK is brought into contact with the peripheral structure PST. For example, the stack structure STK may be brought into contact with the peripheral structure PST using wafer bonding technology. Therefore, the stack structure STK may be positioned on the peripheral structure PST, and the sacrificial structure SFST may be positioned on the stack structure STK.

From the following drawing, in order to specifically describe a region 51 corresponding to the features of the present disclosure, an enlarged view of the corresponding region 51 is referred.

Referring to FIG. 5J, a planarization process may be performed to expose the first material layer 1MT positioned at the uppermost end of the stack structure STK. For example, the sacrificial structure SFST of FIG. 5I and a portion of the cell plugs CP protruding into the sacrificial structure SFST may be removed by the planarization process. A portion of the first capping layer 1CA may be exposed by the planarization process. Subsequently, an etching process for removing a portion of the exposed first capping layer 1CA may be performed. The void VD may or might not be exposed by the etching process for removing a portion of the first capping layer 1CA. That is, because the etching process for removing a portion of the first capping layer 1CA is performed to lower a height of the first capping layer 1CA, the void VD may or might not be exposed according to a size and a position. In the first embodiment described below, a structure in which the void VD is exposed is described as an embodiment.

Referring to FIG. 5K, a second capping layer 2CA for covering an upper portion of the exposed void VD may be formed. The second capping layer 2CA may be formed of a material of which a step coverage is low. For example, the second capping layer 2CA may be formed of an insulating material. For example, the second capping layer 2CA may be formed of an oxide layer. In the second capping layer 2CA, the second capping layer 2CA filled in a region 52 surrounded by the channel layer CH may become the second capping pattern 2CAp. Therefore, a lower surface of the second capping pattern 2CAp may contact the void VD and the first capping layer 1CA.

Referring to FIG. 5L, an etching process or a planarization process for maintaining the second capping pattern 2CAp formed in the cell plug and removing the second capping layer 2CA of FIG. 5K formed on an upper surface of the stack structure may be performed. Subsequently, an ion injection process IMPt for converting an upper partial region 53 of the channel layer CH into the channel junction CHj may be performed. For example, the ion injection process IMPt may be performed as a tilting ion injection process in which an injection angle of impurity is tilted. For example, during the ion injection process IMPt, the injection angle of impurity may be less than or greater than 90 degrees with respect to the X or Y direction. For example, during the ion injection process IMPt, the injection angle of impurity with respect to a substrate may be set to be less than or greater than 90 degrees. As the impurity, an N-type impurity may be used, or a mixture of an N-type impurity and a P-type impurity may be used. When the mixture of the N-type impurity and the P-type impurity is used, the P-type impurity may be injected after the N-type impurity is injected, or the N-type impurity may be injected after the P-type impurity is injected. The N-type impurity may include phosphorus or arsenic, and the P-type impurity may include boron or difuoroboron (BF2).

Because the injection angle of impurity is tilted during the ion injection process IMPt, the impurity may be uniformly injected into an upper region of the channel layer CH. That is, in an embodiment, over injection of impurity may be prevented or mitigated by the second capping pattern 2CAp. For example, when the second capping pattern 2CAp does not exist and only the void VD exists in the upper partial region 53 surrounded by the channel layer CH, an impurity passing through the channel layer CH may be injected into an opposite side channel layer CH through the void VD or injected into a lower region of the void VD. Therefore, in the present embodiment, the second capping pattern 2CAp may prevent or mitigate over injection of impurity, and thus the channel junction CHj of which a concentration of impurity is uniform may be formed in a target region. Because a portion of the channel layer CH where the impurity is injected becomes amorphous, a heat treatment process for changing an amorphous portion to crystalline may be performed after the ion injection process IMPt. For example, a laser heat treatment process may be performed.

Referring to FIG. 5M, the source line SL may be formed on the entire structure including the channel junction CHj and the second capping pattern 2CAp. The source line SL may be formed of a conductive material. For example, the source line SL may be formed of polysilicon.

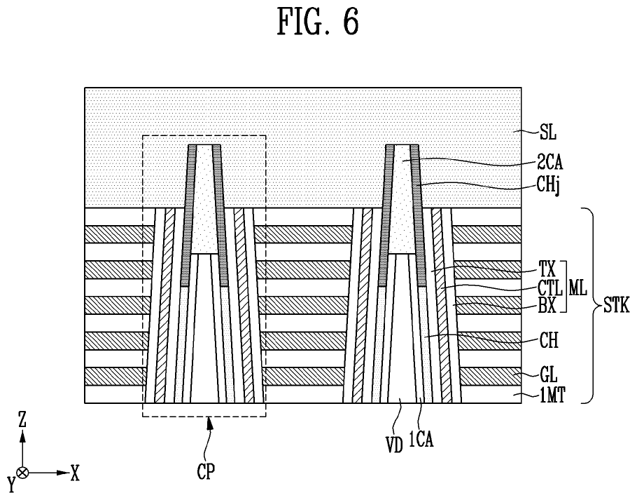

FIG. 6 is a diagram illustrating a memory device according to a second embodiment of the present disclosure.

Referring to FIG. 6, the cell plugs CP of the memory device according to the second embodiment may protrude in a source line SL direction than the cell plugs CP of the memory device according to the first embodiment. For example, a portion of the channel junction CHj and the second capping pattern 2CAp included in the cell plug CP may protrude in the source line SL direction. Because remaining configurations except for the channel junction CHj and the second capping pattern 2CAp are similar to those of the first embodiment, a description of configurations overlapping those of the first embodiment is omitted.

In the memory device according to the second embodiment, the channel junction CHj may protrude from the stack structure STK in the source line SL direction, and the second capping pattern 2CAp may extend to a region surrounded by the protruding channel junction CHj. That is, an upper surface of the channel junction CHj and an upper surface of the second capping pattern 2CAp may be positioned on the same plane. When the channel junction CHj protrudes into the source line SL by passing through the stack structure STK, because a contact surface of the channel junction CHj and the source line SL is increased, when the memory device is operated, a current amount between the channel junction CHj and the source line SL may increase.

A method of manufacturing the memory device according to the second embodiment of the present disclosure is described as follows.

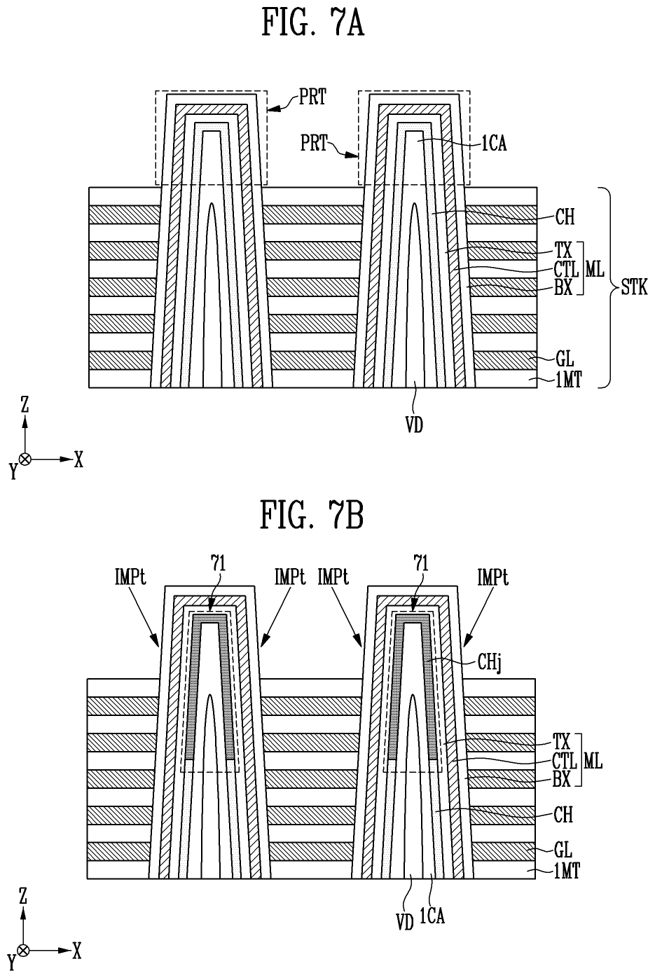

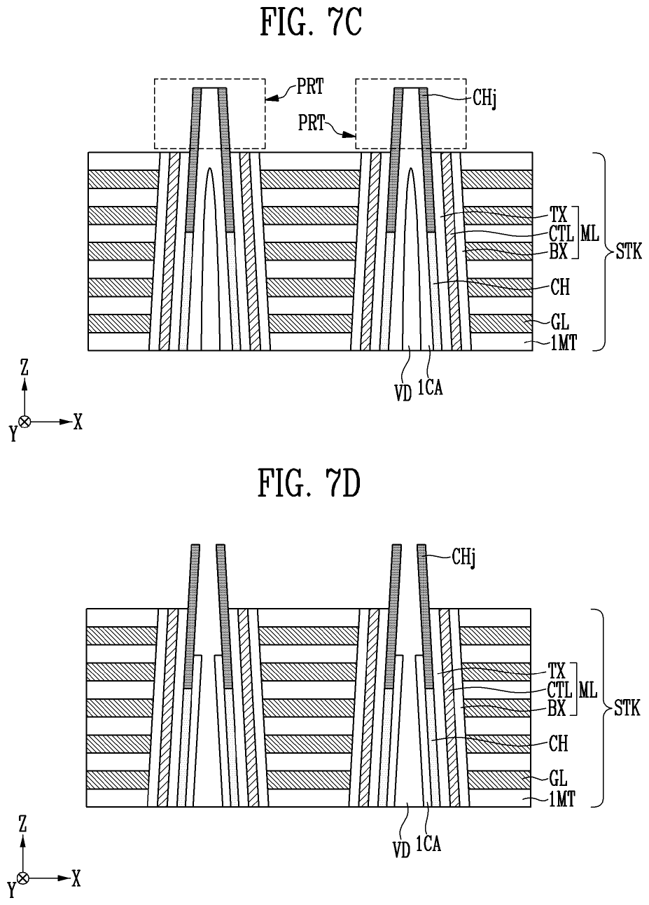

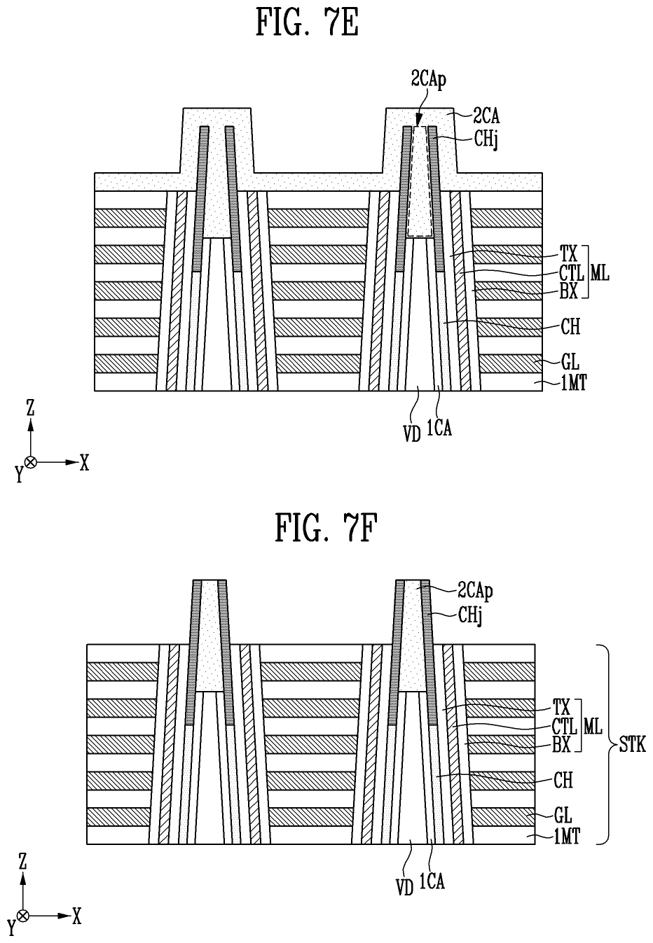

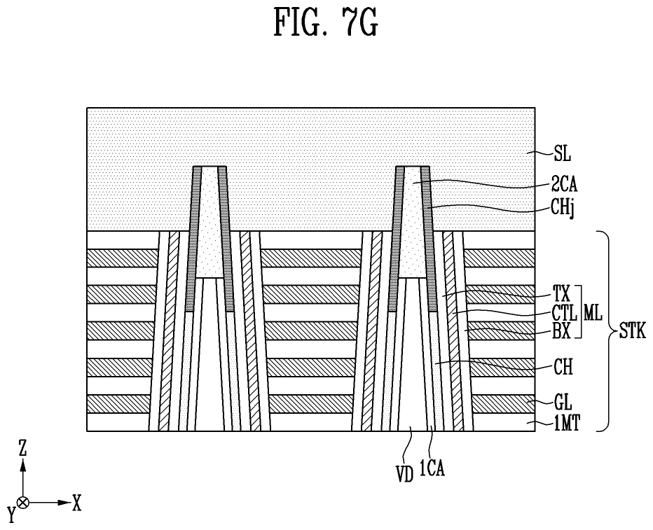

FIGS. 7A to 7G are diagrams illustrating the method of manufacturing the memory device according to the second embodiment of the present disclosure.

In the method of manufacturing the memory device described in the first embodiment, the manufacturing method described with reference to FIGS. 5A to 5I overlaps the method of manufacturing the memory device according to the second embodiment, and thus the method of manufacturing the memory device according to the second embodiment is described after the step described with reference to FIG. 5I.

Referring to FIG. 7A, after the step described with reference to FIG. 5I, an etching process for removing the first substrate 1SUB of FIG. 5I and the sacrificial layer SF of FIG. 5I may be performed. The etching process may be performed as a dry etching process or a wet etching process. The etching process may be performed so that protrusions PRT of the cell plug protruding from the stack structure in the Z direction are maintained. For example, the protrusions PRT may include the first capping layer 1CA, the channel layer CH surrounding the first capping layer 1CA, the tunnel insulating layer TX surrounding the channel layer CH, the charge trap layer CTL surrounding the tunnel insulating layer TX, and the blocking layer BX surrounding the charge trap layer CTL.

Referring to FIG. 7B, an ion injection process IMPt for converting an upper partial region 71 of the channel layer CH into the channel junction CHj may be performed. For example, the ion injection process IMPt may be performed as a tilting ion injection process in which an injection angle of impurity is tilted. For example, during the ion injection process IMPt, the injection angle of impurity may be less than or greater than 90 degrees with respect to the X or Y direction. As the impurity, an N-type impurity may be used, or a mixture of an N-type impurity and a P-type impurity may be used. When the mixture of the N-type impurity and the P-type impurity is used, the P-type impurity may be injected after the N-type impurity is injected, or the N-type impurity may be injected after the P-type impurity is injected. The N-type impurity may include phosphorus or arsenic, and the P-type impurity may include boron or BF2.

Because the injection angle of impurity is tilted during the ion injection process IMPt, the impurity may be injected into the channel layer CH according to energy of the ion injection process IMPt. At this time, in an embodiment, over injection of impurity may be prevented or mitigated by the tunnel insulating layer TX, the charge trap layer CTL, the blocking layer BX, and the first capping layer 1CA surrounding the channel layer CH. Therefore, in an embodiment, the channel junction CHj of which an impurity concentration is uniform may be formed.

Referring to FIG. 7C, an etching process for removing the blocking layer BX, the charge trap layer CTL, and the tunnel insulating layer TX of the protrusions PRT protruding to an upper portion of the stack structure STK may be performed. The etching process may be performed as a dry etching process or a wet etching process. As the tunnel insulating layer TX, the charge trap layer CTL, and the blocking layer BX surrounding the channel junction CHj are removed, the first capping layer 1CA surrounded by the channel junction CHj may be exposed.

Referring to FIG. 7D, an etching process for removing a portion of the first capping layer 1CA surrounded by the channel junction CHj may be performed. At this time, the channel junction CHj protruding to the upper portion of the stack structure STK may be maintained. The void VD may or might not be exposed by the etching process for removing a portion of the first capping layer 1CA. That is, because the etching process for removing a portion of the first capping layer 1CA is performed to lower a height of the first capping layer 1CA, the void VD may or might not be exposed according to a size and a position. In the second embodiment described below, a structure in which the void VD is exposed is described as an embodiment.

Referring to FIG. 7E, a second capping layer 2CA for covering an upper portion of the exposed void VD may be formed. The second capping layer 2CA may be formed of a material of which a step coverage is low. For example, the second capping layer 2CA may be formed of an insulating material. For example, the second capping layer 2CA may be formed of an oxide layer. A portion of the second capping layer 2CA surrounded by the channel junction CHj may become the second capping pattern 2CAp. A lower surface of the second capping pattern 2CAp may contact the void VD and the first capping layer 1CA. Therefore, the second capping pattern 2CAp may be surrounded by the channel layer CH.

Referring to FIG. 7F, an etching process for removing the second capping layer 2CA surrounding an outside of the channel junction CHj and the stack structure STK may be performed. During the etching process, because an exposed area of the second capping pattern 2CAp is less than that of the second capping layer 2CA, even though the second capping pattern 2CAp is etched, the second capping pattern 2CAp may be etched more slowly than the second capping layer 2CA. Therefore, even though the second capping layer 2CA is removed, the second capping pattern 2CAp may remain in a region surrounded by the channel junction CHj.

Referring to FIG. 7G, the source line SL may be formed on the entire structure including the channel junction CHj and the second capping pattern 2CAp. The source line SL may be formed of a conductive material. For example, the source line SL may be formed of polysilicon.

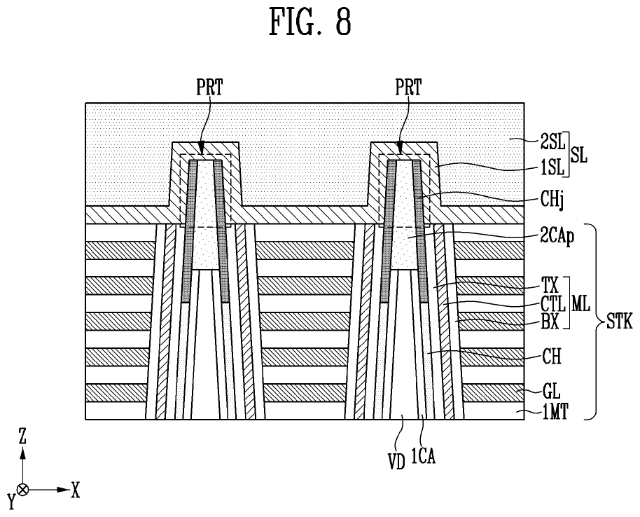

FIG. 8 is a diagram illustrating a memory device according to a third embodiment of the present disclosure.

Referring to FIG. 8, the source line SL of the memory device according to the third embodiment may include first and second source layers 1SL and 2SL. For example, the first source layer 1SL may be formed along an upper surface of the protrusions PRT and the stack structure STK of the cell plugs, and the second source layer 2SL may be formed on the first source layer 1SL. Because remaining configurations except for the source line SL are similar to those of the second embodiment, a description of configurations overlapping those of the second embodiment is omitted.

A method of manufacturing the memory device according to the third embodiment of the present disclosure is described as follows.

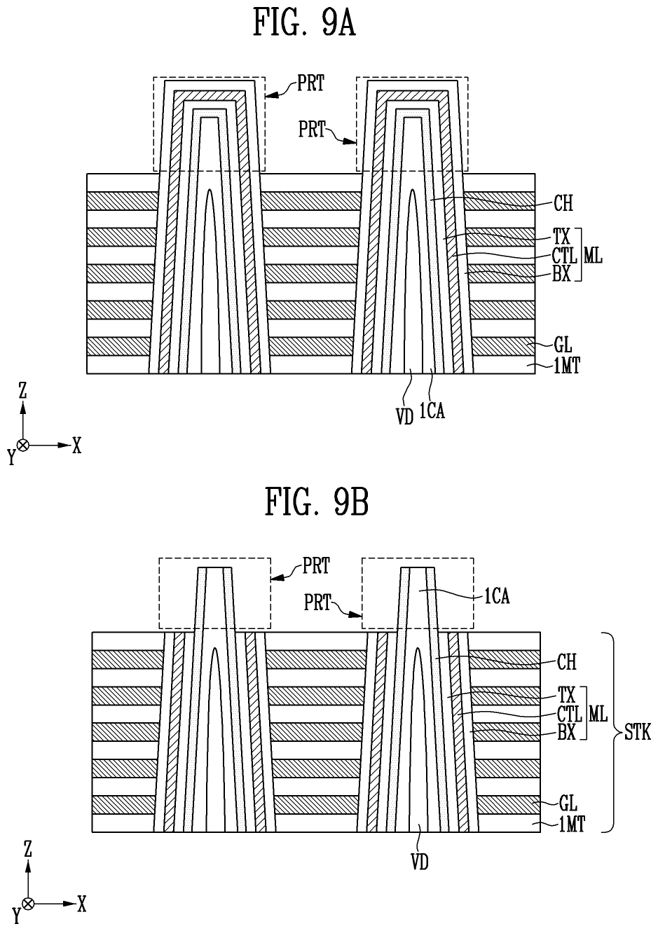

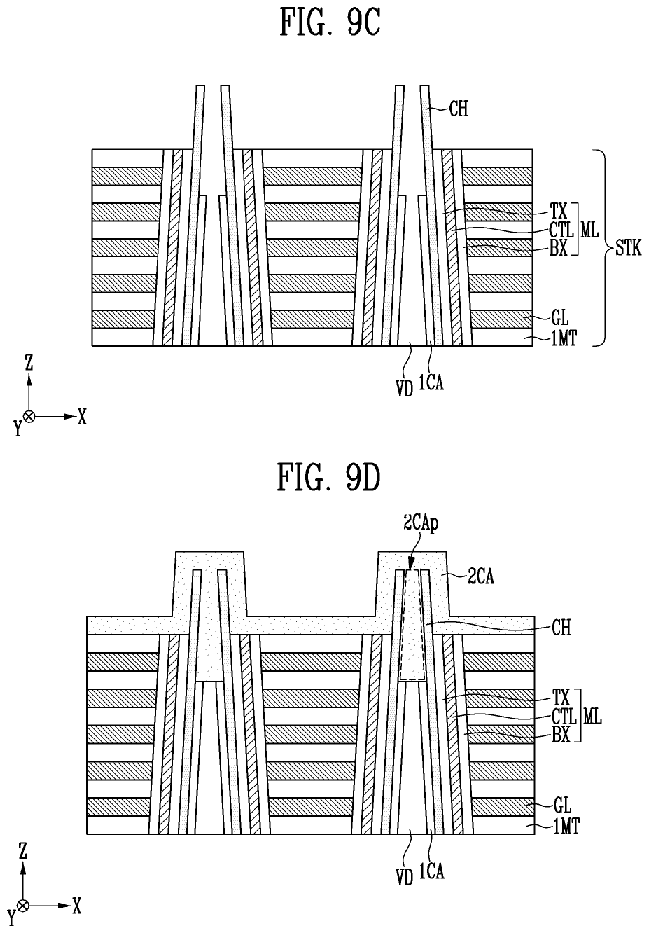

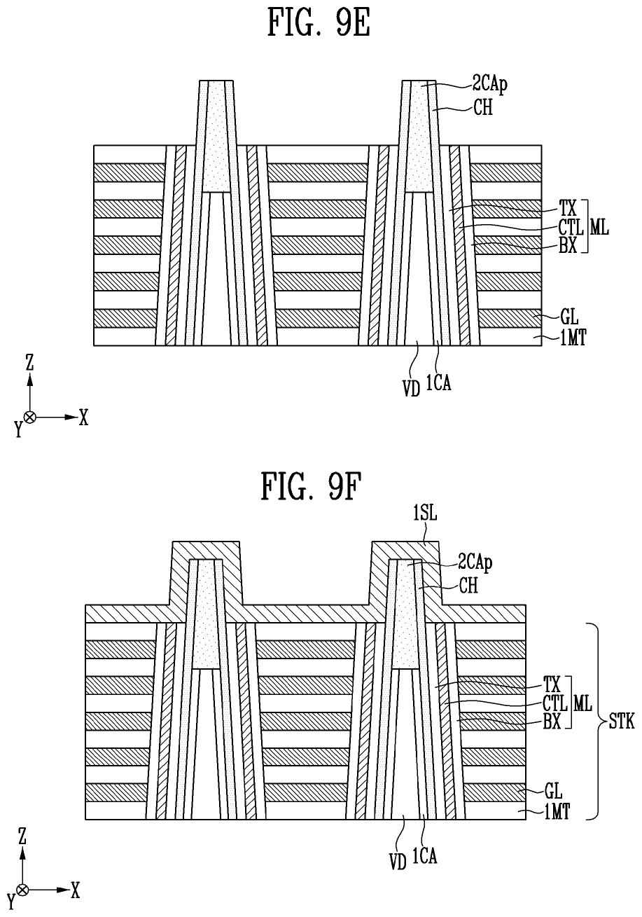

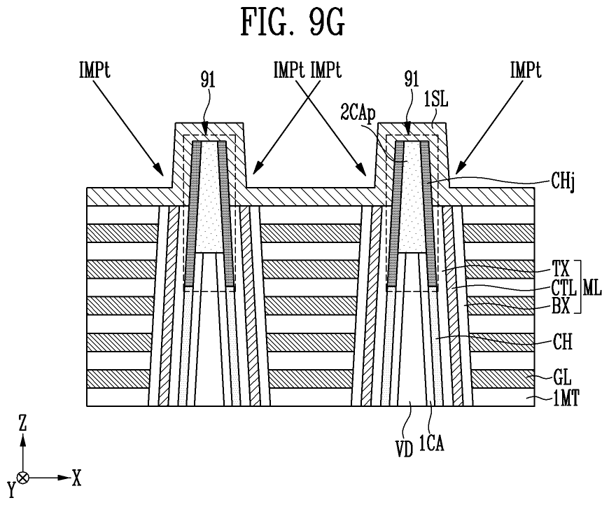

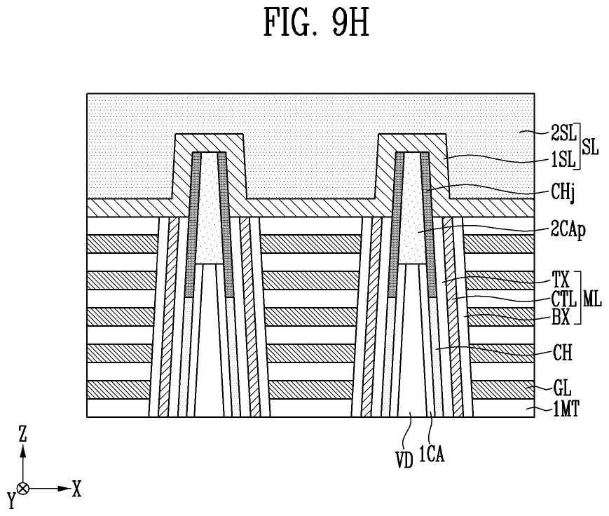

FIGS. 9A to 9H are diagrams illustrating the method of manufacturing the memory device according to the third embodiment of the present disclosure.

Referring to FIG. 9A, after the step described with reference to FIG. 5I, an etching process for removing the first substrate 1SUB of FIG. 5I and the sacrificial layer SF of FIG. 5I may be performed. The etching process may be performed as a dry etching process or a wet etching process. The etching process may be performed so that protrusions PRT of the cell plug protruding from the stack structure in the Z direction are maintained. For example, the protrusions PRT may include the first capping layer 1CA, the channel layer CH surrounding the first capping layer 1CA, the tunnel insulating layer TX surrounding the channel layer CH, the charge trap layer CTL surrounding the tunnel insulating layer TX, and the blocking layer BX surrounding the charge trap layer CTL.

Referring to FIG. 9B, an etching process for removing the blocking layer BX, the charge trap layer CTL, and the tunnel insulating layer TX protruding to an upper portion of the stack structure STK may be performed. The etching process may be performed as a dry etching process or a wet etching process. As the tunnel insulating layer TX, the charge trap layer CTL, and the blocking layer BX surrounding the channel layer CH are removed, the first capping layer 1CA surrounded by the channel junction CHj may be exposed.

Referring to FIG. 9C, an etching process for removing a portion of the first capping layer 1CA surrounded by the channel junction CHj may be performed. At this time, the channel junction CHj protruding to the upper portion of the stack structure STK may be maintained. The void VD may or might not be exposed by the etching process for removing a portion of the first capping layer 1CA. That is, because the etching process for removing a portion of the first capping layer 1CA is performed to lower a height of the first capping layer 1CA, the void VD may or might not be exposed according to a size and a position. In the third embodiment described below, a structure in which the void VD is exposed is described as an embodiment.

Referring to FIG. 9D, a second capping layer 2CA for covering an upper portion of the exposed void VD may be formed. The second capping layer 2CA may be formed of a material of which a step coverage is low. For example, the second capping layer 2CA may be formed of an insulating material. For example, the second capping layer 2CA may be formed of an oxide layer. A portion of the second capping layer 2CA surrounded by the channel layer CH may become the second capping pattern 2CAp. A lower surface of the second capping pattern 2CAp may contact the void VD and the first capping layer 1CA. Therefore, the second capping pattern 2CAp may be surrounded by the channel layer CH.

Referring to FIG. 9E, an etching process for removing the second capping layer 2CA of FIG. 9D surrounding an outside of the channel layer CH and the stack structure STK may be performed. During the etching process, because an exposed area of the second capping pattern 2CAp is less than that of the second capping layer 2CA, even though the second capping pattern 2CAp is etched, the second capping pattern 2CAp may be etched more slowly than the second capping layer 2CA. Therefore, even though the second capping layer 2CA is removed, the second capping pattern 2CAp may remain in a region surrounded by the channel layer CH.

Referring to FIG. 9F, the first source layer 1SL may be formed along a surface of the stack structure STK, and the second capping pattern 2CAp and the channel layer CH protruding from the stack structure STK. The first source layer 1SL may be formed of a conductive material. For example, the first source layer 1SL may be formed of polysilicon. The first source layer 1SL may be used as a seed layer when forming a second source layer 2SL of FIG. 9H corresponding to a main source line.

Referring to FIG. 9G, an ion injection process IMPt for converting an upper partial region 91 of the channel layer CH into the channel junction CHj may be performed. For example, the ion injection process IMPt may be performed as a tilting ion injection process in which an injection angle of impurity is tilted. For example, during the ion injection process IMPt, the injection angle of impurity may be less than or greater than 90 degrees with respect to the X or Y direction. As the impurity, an N-type impurity may be used, or a mixture of an N-type impurity and a P-type impurity may be used. When the mixture of the N-type impurity and the P-type impurity is used, the P-type impurity may be injected after the N-type impurity is injected, or the N-type impurity may be injected after the P-type impurity is injected. The N-type impurity may include phosphorus or arsenic, and the P-type impurity may include boron or BF2.

Because the injection angle of impurity is tilted during the ion injection process IMPt, the impurity may be injected into the channel layer CH according to energy of the ion injection process IMPt. At this time, in an embodiment, over injection of impurity may be prevented or mitigated by the second capping pattern 2CAp. For example, when the second capping pattern 2CAp does not exist and only the void VD exists in the upper partial region 91 surrounded by the channel layer CH, an impurity passing through the channel layer CH may be injected into an opposite side channel layer CH through the void VD or injected into a lower region of the void VD. Therefore, in the present embodiment, the second capping pattern 2CAp may prevent or mitigate over injection of impurity, and thus the channel junction CHj of which a concentration of impurity is uniform may be formed in a target region.

Referring to FIG. 9H, the second source layer 2SL may be formed on the first source layer 1SL. The second source layer 2SL may be formed of the same material as the first source layer 1SL. For example, the second source layer 2SL may be formed of polysilicon. When the second source layer 2SL is formed, because the first source layer 1SL may be used as a seed layer, the second source layer 2SL may be formed. When the second source layer 2SL is formed, the source line SL including the first and second source layers 1SL and 2SL may be formed.

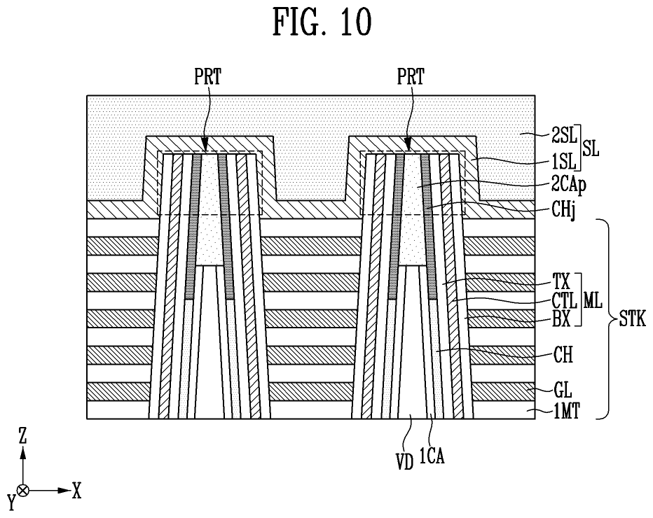

FIG. 10 is a diagram illustrating a memory device according to a fourth embodiment of the present disclosure.

Referring to FIG. 10, in the memory device according to the fourth embodiment, the protrusions PRT of the cell plugs may include the tunnel insulating layer TX, the charge trap layer CTL, and the blocking layer BX. For example, the tunnel insulating layer TX, the charge trap layer CTL, and the blocking layer BX may be positioned on a side surface of the channel junction CHj protruding in the Z direction from the stack structure STK, and an upper surface of the second capping pattern 2CAp, the channel junction CHj, the tunnel insulating layer TX, the charge trap layer CTL, and the blocking layer BX may contact the first source layer 1SL.

Because remaining configurations except for the protrusions PRT are similar to those of the third embodiment, a description of configurations overlapping those of the third embodiment is omitted.

A method of manufacturing the memory device according to the fourth embodiment of the present disclosure is described as follows.

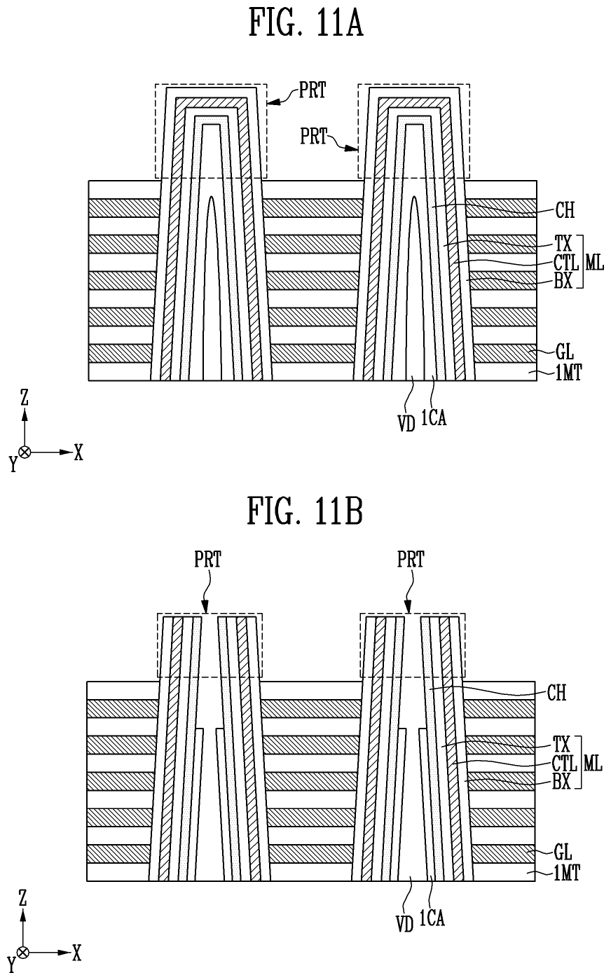

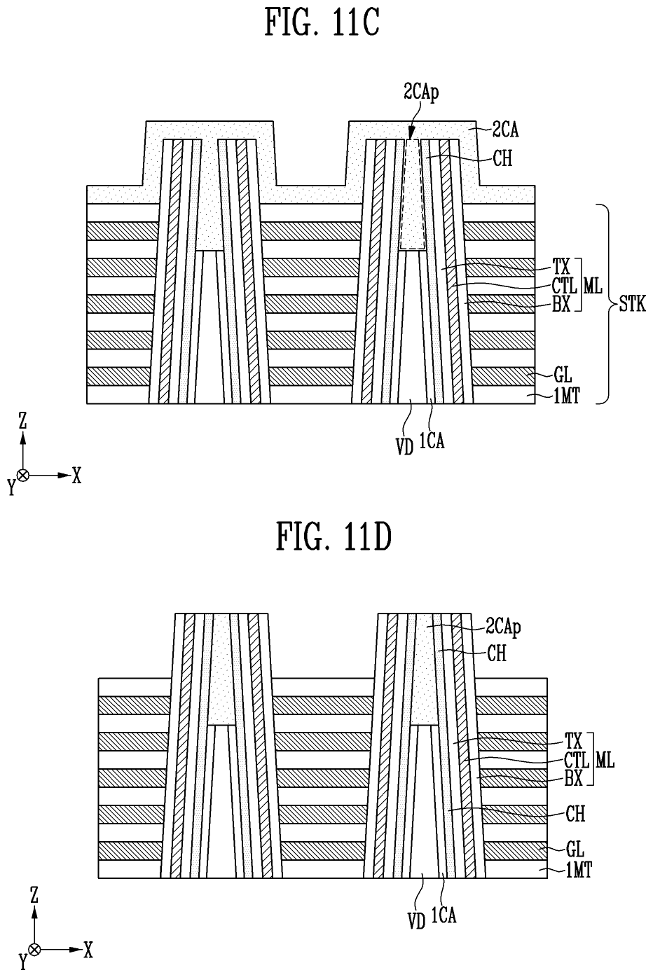

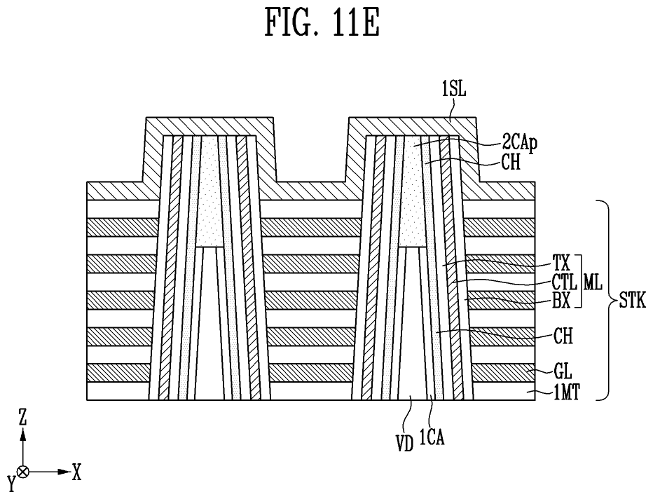

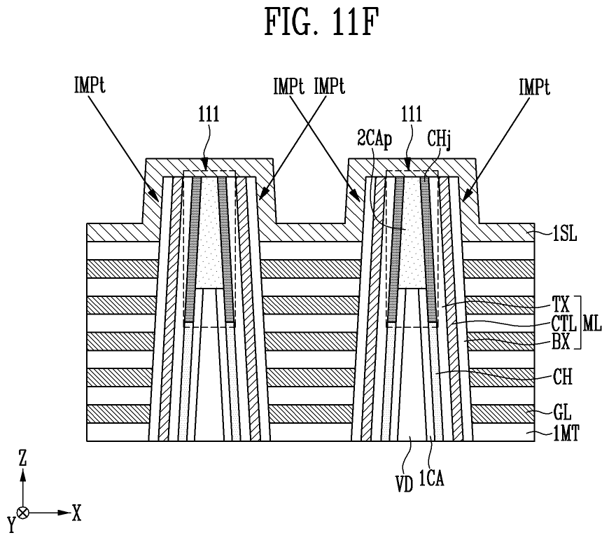

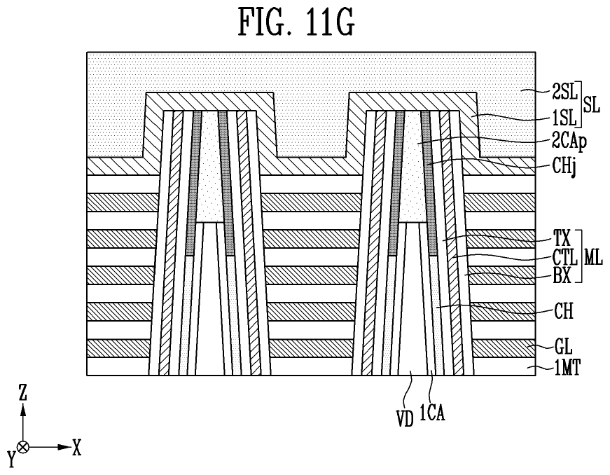

FIGS. 11A to 11G are diagrams illustrating the method of manufacturing the memory device according to the fourth embodiment of the present disclosure.

Referring to FIG. 11A, after the step described with reference to FIG. 5I, an etching process for removing the first substrate 1SUB of FIG. 5I and the sacrificial layer SF of FIG. 5I may be performed. The etching process may be performed as a dry etching process or a wet etching process. The etching process may be performed so that protrusions PRT of the cell plug protruding from the stack structure in the Z direction are maintained. For example, the protrusions PRT may include the first capping layer 1CA, the channel layer CH surrounding the first capping layer 1CA, the tunnel insulating layer TX surrounding the channel layer CH, the charge trap layer CTL surrounding the tunnel insulating layer TX, and the blocking layer BX surrounding the charge trap layer CTL.

Referring to FIG. 11B, the blocking layer BX, the charge trap layer CTL, the tunnel insulating layer TX, and the channel layer CH formed on the protrusions PRT may be removed to expose a portion of the first capping layer 1CA, and an etching process for removing the exposed portion of the first capping layer 1CA may be performed. The etching process may be performed as a dry etching process or a wet etching process. During the etching process, the channel junction CHj, the tunnel insulating layer TX, the charge trap layer CTL, and the blocking layer BX positioned on a side of the protrusions PRT protruding to the upper portion of the stack structure STK may be maintained. The void VD may or might not be exposed by the etching process for removing a portion of the first capping layer 1CA. That is, because the etching process for removing a portion of the first capping layer 1CA is performed to lower a height of the first capping layer 1CA, the void VD may or might not be exposed according to a size and a position. In the fourth embodiment described below, a structure in which the void VD is exposed is described as an embodiment.

Referring to FIG. 11C, a second capping layer 2CA for covering an upper portion of the exposed void VD may be formed. The second capping layer 2CA may be formed of a material of which a step coverage is low. For example, the second capping layer 2CA may be formed of an insulating material. For example, the second capping layer 2CA may be formed of an oxide layer. A portion of the second capping layer 2CA surrounded by the channel layer CH may become the second capping pattern 2CAp. The second capping pattern 2CAp may contact the void VD and the first capping layer 1CA. Therefore, the second capping pattern 2CAp may be surrounded by the channel layer CH.

Referring to FIG. 11D, an etching process for removing the second capping layer 2CA except for the second capping pattern 2CAp surrounded by the channel layer CH may be performed. During the etching process, since an exposed area of the second capping pattern 2CAp is less than that of the second capping layer 2CA, even though the second capping pattern 2CAp is etched, the second capping pattern 2CAp may be etched more slowly than the second capping layer 2CA. Therefore, even though the second capping layer 2CA is removed, the second capping pattern 2CAp may remain in a region surrounded by the channel layer CH.

Referring to FIG. 11E, the first source layer 1SL may be formed along a surface of the stack structure STK and the protrusions PRT. The first source layer 1SL may be formed of a conductive material. For example, the first source layer 1SL may be formed of polysilicon. The first source layer 1SL may be used as a seed layer when forming a second source layer 2SL of FIG. 11G corresponding to a main source line.

Referring to FIG. 11F, an ion injection process IMPt for converting an upper partial region 111 of the channel layer CH into the channel junction CHj may be performed. For example, the ion injection process IMPt may be performed as a tilting ion injection process in which an injection angle of impurity is tilted. For example, during the ion injection process IMPt, the injection angle of impurity may be less than or greater than 90 degrees with respect to the X or Y direction. As the impurity, an N-type impurity may be used, or a mixture of an N-type impurity and a P-type impurity may be used. When the mixture of the N-type impurity and the P-type impurity is used, the P-type impurity may be injected after the N-type impurity is injected, or the N-type impurity may be injected after the P-type impurity is injected. The N-type impurity may include phosphorus or arsenic, and the P-type impurity may include boron or BF2.

Because the injection angle of impurity is tilted during the ion injection process IMPt, the impurity may be injected into the channel layer CH according to energy of the ion injection process IMPt. At this time, in an embodiment, over injection of impurity may be prevented or mitigated by the second capping pattern 2CAp. For example, when the second capping pattern 2CAp does not exist and only the void VD exists in the upper partial region 91 surrounded by the channel layer CH, an impurity passing through the channel layer CH may be injected into an opposite side channel layer CH through the void VD or injected into a lower region of the void VD. Therefore, in the present embodiment, the second capping pattern 2CAp may prevent or mitigate over injection of impurity, and thus the channel junction CHj of which a concentration of impurity is uniform may be formed in a target region.

Referring to FIG. 11G, the second source layer 2SL may be formed on the first source layer 1SL. The second source layer 2SL may be formed of the same material as the first source layer 1SL. For example, the second source layer 2SL may be formed of polysilicon. When the second source layer 2SL is formed, because the first source layer 1SL may be used as a seed layer, the second source layer 2SL may be formed. When the second source layer 2SL is formed, the source line SL including the first and second source layers 1SL and 2SL may be formed.

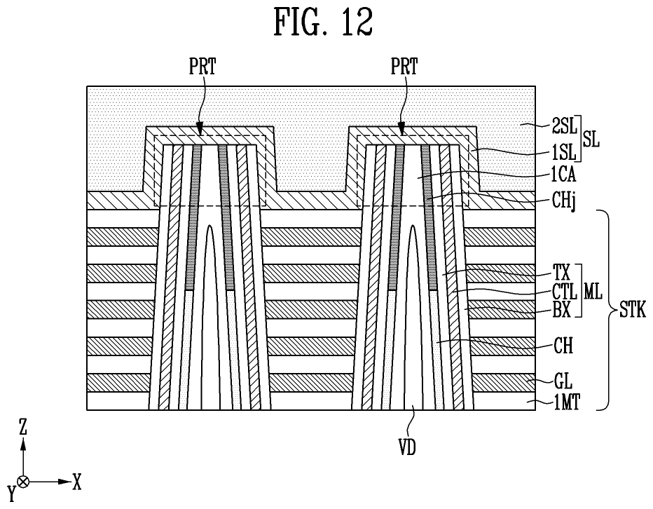

FIG. 12 is a diagram illustrating a memory device according to a fifth embodiment of the present disclosure.

Referring to FIG. 12, in the memory device according to the fifth embodiment, the protrusions PRT of the cell plugs may include the first capping layer 1CA, the channel junction CHj, the tunnel insulating layer TX, the charge trap layer CTL, and the blocking layer BX. For example, the channel junction CHj, the tunnel insulating layer TX, the charge trap layer CTL, and the blocking layer BX may be sequentially positioned on a side surface of the first capping layer 1CA protruding in the Z direction from the stack structure STK, and an upper surface of the first capping layer 1CA, the channel junction CHj, the tunnel insulating layer TX, the charge trap layer CTL, and the blocking layer BX and a side surface of the blocking layer BX may contact the first source layer 1SL.

Because remaining configurations except for the protrusions PRT are similar to those of the fourth embodiment, a description of configurations overlapping those of the fourth embodiment is omitted.

A method of manufacturing the memory device according to the fifth embodiment of the present disclosure is described as follows.

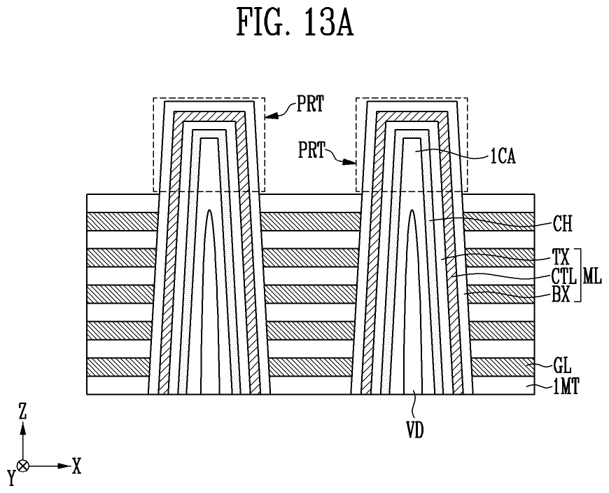

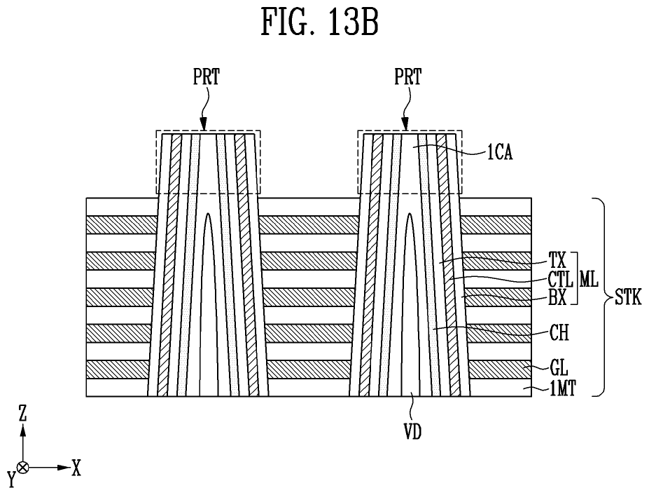

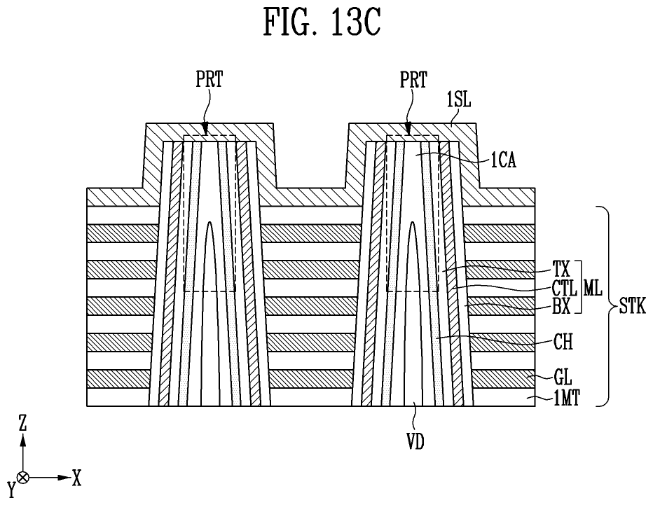

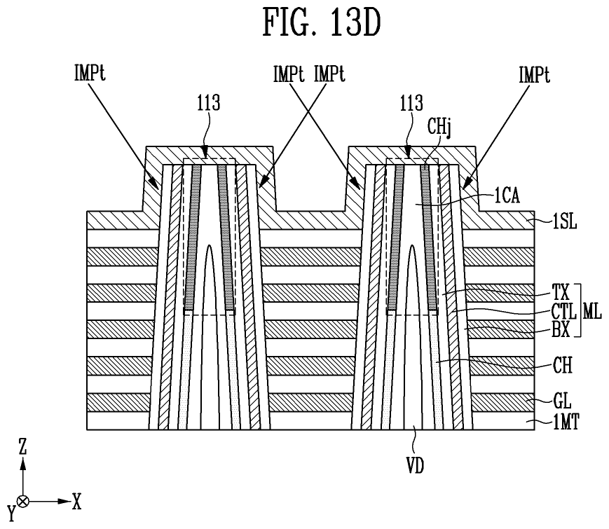

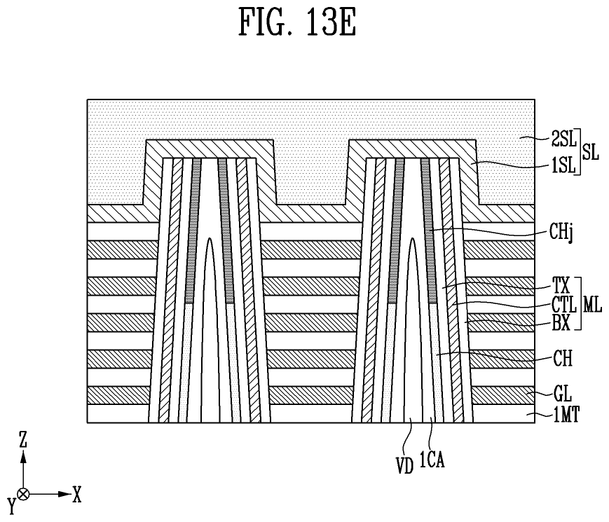

FIGS. 13A to 13E are diagrams illustrating the method of manufacturing the memory device according to the fifth embodiment of the present disclosure.

Referring to FIG. 13A, after the step described with reference to FIG. 5I, an etching process for removing the first substrate 1SUB of FIG. 5I and the sacrificial layer SF of FIG. 5I may be performed. The etching process may be performed as a dry etching process or a wet etching process. The etching process may be performed so that protrusions PRT of the cell plug protruding from the stack structure in the Z direction are maintained. For example, the protrusions PRT may include the first capping layer 1CA, the channel layer CH surrounding the first capping layer 1CA, the tunnel insulating layer TX surrounding the channel layer CH, the charge trap layer CTL surrounding the tunnel insulating layer TX, and the blocking layer BX surrounding the charge trap layer CTL.

Referring to FIG. 13B, an etching process for exposing a portion of the first capping layer 1CA by removing the blocking layer BX, the charge trap layer CTL, the tunnel insulating layer TX, and the channel layer CH formed on the protrusions PRT may be performed. The etching process may be performed as a dry etching process or a wet etching process. During the etching process, the channel junction CHj, the tunnel insulating layer TX, the charge trap layer CTL, and the blocking layer BX positioned on a side of the protrusions PRT protruding to the upper portion of the stack structure STK may be maintained.

Referring to FIG. 13C, the first source layer 1SL may be formed along a surface of the stack structure STK and the protrusions PRT. The first source layer 1SL may be formed of a conductive material. For example, the first source layer 1SL may be formed of polysilicon. The first source layer 1SL may be used as a seed layer when forming a second source layer 2SL of FIG. 13E corresponding to a main source line.

Referring to FIG. 13D, an ion injection process IMPt for converting an upper partial region 113 of the channel layer CH into the channel junction CHj may be performed. For example, the ion injection process IMPt may be performed as a tilting ion injection process in which an injection angle of impurity is tilted. For example, during the ion injection process IMPt, the injection angle of impurity may be less than or greater than 90 degrees with respect to the X or Y direction. As the impurity, an N-type impurity may be used, or a mixture of an N-type impurity and a P-type impurity may be used. When the mixture of the N-type impurity and the P-type impurity is used, the P-type impurity may be injected after the N-type impurity is injected, or the N-type impurity may be injected after the P-type impurity is injected. The N-type impurity may include phosphorus or arsenic, and the P-type impurity may include boron or BF2.

Because the injection angle of impurity is tilted during the ion injection process IMPt, the impurity may be injected into the channel layer CH according to energy of the ion injection process IMPt. At this time, in an embodiment, over injection of impurity may be prevented or mitigated by the first capping layer 1CA. For example, when the first capping layer 1CA does not exist and only the void VD exists in the upper partial region 113 surrounded by the channel layer CH, an impurity passing through the channel layer CH may be injected into an opposite side channel layer CH through the void VD or injected into a lower region of the void VD. Therefore, in the present embodiment, the first capping layer 1CA may prevent or mitigate over injection of impurity, and thus the channel junction CHj of which a concentration of impurity is uniform may be formed in a target region.

Referring to FIG. 13E, the second source layer 2SL may be formed on the first source layer 1SL. The second source layer 2SL may be formed of the same material as the first source layer 1SL. For example, the second source layer 2SL may be formed of polysilicon. When the second source layer 2SL is formed, because the first source layer 1SL may be used as a seed layer, the second source layer 2SL may be formed. When the second source layer 2SL is formed, the source line SL including the first and second source layers 1SL and 2SL may be formed.

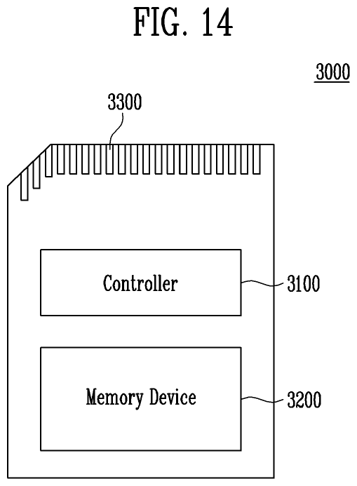

FIG. 14 is a diagram illustrating a memory card system to which a memory device of the present disclosure is applied.

Referring to FIG. 14, the memory card system 3000 includes a controller 3100, a memory device 3200, and a connector 3300.

The controller 3100 is connected to the memory device 3200. The controller 3100 is configured to access the memory device 3200. For example, the controller 3100 may be configured to control a program, read, or erase operation of the memory device 3200 or to control a background operation. The controller 3100 is configured to provide an interface between the memory device 3200 and a host. The controller 3100 is configured to drive firmware for controlling the memory device 3200. For example, the controller 3100 may include components such as a random access memory (RAM), a processing unit, a host interface, a memory interface, and an error correction circuit.

The controller 3100 may communicate with an external device through the connector 3300. The controller 3100 may communicate with an external device (for example, the host) according to a specific communication standard. For example, the controller 3100 is configured to communicate with an external device through at least one of various communication standards such as a universal serial bus (USB), a multimedia card (MMC), an embedded MMC (eMMC), a peripheral component interconnection (PCI), a PCI express (PCI-E), an advanced technology attachment (ATA), a serial-ATA, a parallel-ATA, a small computer system interface (SCSI), an enhanced small disk interface (ESDI), integrated drive electronics (IDE), FireWire, a universal flash storage (UFS), Wi-Fi, Bluetooth, and an NVMe. For example, the connector 3300 may be defined by at least one of the various communication standards described above.

The memory device 3200 may include a plurality of memory cells, and may be configured identically to the memory device 100 shown in FIG. 1.

The controller 3100 and the memory device 3200 may be integrated into one semiconductor device to configure a memory card. For example, the controller 3100 and the memory device 3200 may be integrated into one semiconductor device to configure a memory card such as a PC card (personal computer memory card international association (PCMCIA)), a compact flash card (CF), a smart media card (SM or SMC), a memory stick, a multimedia card (MMC, RS-MMC, MMCmicro, or eMMC), an SD card (SD, miniSD, microSD, or SDHC), and a universal flash storage (UFS).

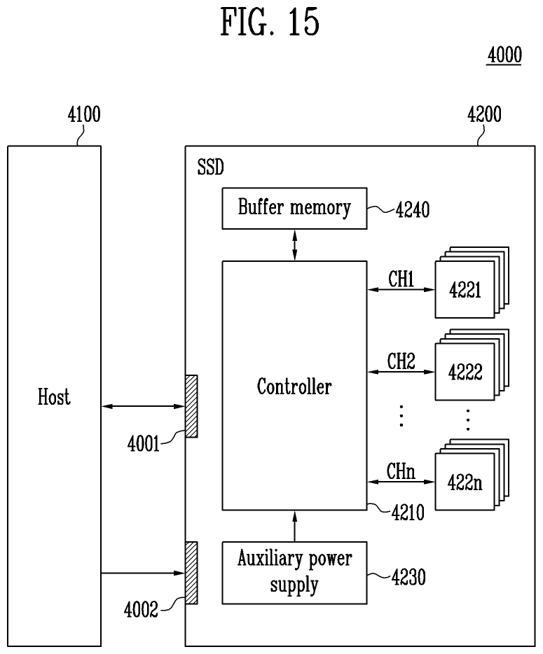

FIG. 15 is a diagram illustrating a solid state drive (SSD) system to which a memory device of the present disclosure is applied.

Referring to FIG. 15, the SSD system 4000 includes a host 4100 and an SSD 4200. The SSD 4200 exchanges a signal with the host 4100 through a signal connector 4001 and receives power through a power connector 4002. The SSD 4200 includes a controller 4210, a plurality of memory devices 4221 to 422n, an auxiliary power supply 4230, and a buffer memory 4240.

The controller 4210 may control the plurality of memory devices 4221 to 422n in response to the signal received from the host 4100. For example, the signal may be signals based on an interface between the host 4100 and the SSD 4200. For example, the signal may be a signal defined by at least one of interfaces such as a universal serial bus (USB), a multimedia card (MMC), an embedded MMC (eMMC), a peripheral component interconnection (PCI), a PCI express (PCI-E), an advanced technology attachment (ATA), a serial-ATA, a parallel-ATA, a small computer system interface (SCSI), an enhanced small disk interface (ESDI), integrated drive electronics (IDE), FireWire, a universal flash storage (UFS), Wi-Fi, Bluetooth, and an NVMe.

The plurality of memory devices 4221 to 422n may include a plurality of memory cells configured to store data. Each of the plurality of memory devices 4221 to 422n may be configured identically to the memory device 100 shown in FIG. 1. The plurality of memory devices 4221 to 422n may communicate with the controller 4210 through channels CH1 to CHn.

The auxiliary power supply 4230 is connected to the host 4100 through the power connector 4002. The auxiliary power supply 4230 may receive a power voltage from the host 4100 and charge the power voltage. The auxiliary power supply 4230 may provide a power voltage of the SSD 4200 when power supply from the host 4100 is not smooth. For example, the auxiliary power supply 4230 may be positioned in the SSD 4200 or may be positioned outside the SSD 4200. For example, the auxiliary power supply 4230 may be positioned on a main board and may provide auxiliary power to the SSD 4200.

The buffer memory 4240 operates as a buffer memory of the SSD 4200. For example, the buffer memory 4240 may store data received from the host 4100 or data received from the plurality of memory devices 4221 to 422n, or may store meta data (for example, a mapping table) of the memory devices 4221 to 422n. The buffer memory 4240 may include a volatile memory such as a DRAM, an SDRAM, a DDR SDRAM, and an LPDDR SDRAM, or a nonvolatile memory such as an FRAM, a ReRAM, an STT-MRAM, and a PRAM.

What is claimed is:

1. A memory device comprising:
a channel layer passing through gate lines, wherein the gate lines are stacked and spaced apart from each other;
a channel junction extending from the channel layer;
a capping layer surrounded by the channel layer;
a void surrounded by the capping layer;
a capping pattern surrounded by the channel junction and contacting an upper portion of the capping layer and the void; and
a source line positioned on the gate lines and contacting the channel junction.

2. The memory device of claim 1, wherein the channel junction has an impurity concentration higher than that of the channel layer.

3. The memory device of claim 1, wherein the channel junction is formed by injecting an N-type impurity into the channel layer.

4. The memory device of claim 3, wherein the N-type impurity includes phosphorus or arsenic.

5. The memory device of claim 1, wherein the channel junction is formed by injecting an N-type impurity and a P-type impurity into the channel layer.

6. The memory device of claim 5,
wherein the N-type impurity includes phosphorus or arsenic, and
wherein the P-type impurity includes boron or BF2.

7. The memory device of claim 1, wherein the channel layer is polysilicon.

8. The memory device of claim 1, further comprising:
a tunnel insulating layer surrounding a side surface of the channel layer;
a charge trap layer surrounding a side surface of the tunnel insulating layer; and
a blocking layer surrounding a side surface of the charge trap layer.

9. The memory device of claim 8, wherein an upper surface of the tunnel insulating layer, the charge trap layer, and the blocking layer is positioned on substantially the same plane as an upper surface of the channel junction and the capping pattern.

10. The memory device of claim 9, wherein the source line comprises:
a first source layer contacting the upper surface of the channel junction and the capping pattern; and
a second source layer positioned on the first source layer.

11. The memory device of claim 8, wherein the channel junction protrudes from the channel layer, the charge trap layer, and the blocking layer into the source line.

12. The memory device of claim 11, wherein the source line comprises:
a first source layer contacting a side surface and an upper surface of the protruding channel junction and contacting an upper surface of the capping pattern; and
a second source layer positioned on the first source layer.

13. The memory device of claim 1, wherein the capping pattern and the capping layer are an insulating material.

14. A memory device comprising:
a stack structure including insulating layers and gate lines alternately stacked;
a cell plug included in the stack structure and passing through the insulating layers and the gate lines;
a channel layer included in the cell plug, a void surrounded by the channel layer, a tunnel insulating layer surrounding the channel layer, a charge trap layer surrounding the tunnel insulating layer, and a blocking layer surrounding the charge trap layer;
a channel junction included in the cell plug and extending from the channel layer;
a capping pattern included in the cell plug and surrounded by at least a portion of the channel layer and the channel junction; and
a source line positioned on the stack structure and contacting the channel junction and the capping pattern.

15. The memory device of claim 14, further comprising:
a capping layer positioned between the channel layer and the void and surrounding the void.

16. The memory device of claim 14, wherein an upper surface of the tunnel insulating layer, the charge trap layer, the blocking layer, the channel junction, and the capping pattern is substantially flat with an upper surface of the stack structure.

17. The memory device of claim 14,
wherein the tunnel insulating layer, the charge trap layer, and the blocking layer are flat with the upper surface of the stack structure, and
wherein the channel junction and the capping pattern protrude in an upper direction from the stack structure.

18. The memory device of claim 17, wherein the source line contacts a side surface of the protruding channel junction.

19. The memory device of claim 17, wherein the source line comprises:
a first source layer contacting an upper surface of the stack structure, the tunnel insulating layer, the charge trap layer, and the blocking layer, a side surface of the channel junction, and an upper surface of the channel junction and the capping pattern; and
a second source layer positioned on the first source layer.

20. The memory device of claim 14, wherein the tunnel insulating layer, the charge trap layer, the blocking layer, the channel junction, and the capping pattern protrude in an upper direction from the stack structure.

21. The memory device of claim 20, wherein the source line comprises:
a first source layer contacting an upper surface of the stack structure, a side surface of the blocking layer, and an upper surface of the tunnel insulating layer, the charge trap layer, the blocking layer, the channel junction, and the capping pattern; and
a second source layer positioned on the first source layer.
